(19) United States
(12) Patent Application Publication
(10) Pub. No.: US 2025/0243371 A1
(43) Pub. Date: Jul. 31, 2025

(54) NANOPARTICLE-CONTAINING MEDIA EXHIBITING ENHANCED OPTICAL TRANSPARENCY, RELATED NANOPARTICLES, AND ASSOCIATED SYSTEMS AND METHODS

(71) Applicants: The University of Chicago, Chicago, IL (US); UChicago Argonne, LLC, Chicago, IL (US)

(72) Inventors: Matthew Tirrell, Chicago, IL (US); Wei Chen, Naperville, IL (US); Sovan Banerjee, Chicago, IL (US)

(73) Assignees: The University of Chicago, Chicago, IL (US); UChicago Argonne, LLC, Chicago, IL (US)

(21) Appl. No.: 19/101,885

(22) PCT Filed: Aug. 7, 2023
(86) PCT No.: PCT/US2023/029618

§ 371 Date: Feb. 6, 2025

Related U.S. Application Data
(60) Provisional application No. 63/395,989, filed on Aug. 8, 2022.

(51) Int. Cl. C09D 5/26; C09C 3/00; C09C 3/06; C09C 3/10; C09D 5/29; C09D 7/40; C09D 7/62; C09K 9/00

(52) U.S. Cl. CPC C09D 5/26; C09C 3/006; C09C 3/063; C09C 3/10; C09D 5/29; C09D 7/62; C09D 7/68; C09K 9/00; C01P 2004/62; C01P 2004/84; C01P 2006/32; C01P 2006/60

(57) ABSTRACT

The present disclosure is generally directed to nanoparticle-containing media exhibiting enhanced optical transparency, related nanoparticles, and associated systems and methods. In certain embodiments, the refractive index (RI) of a nanoparticle comprising thermochromic material (such as VO2) can be made closer to the refractive index of a surrounding medium by tethering a material (such as a gradient copolymer) to the core region of the nanoparticle to modify the refractive index of the nanoparticle. Modifying the refractive index of the nanoparticle to be closer to the refractive index of the medium that contains the nanoparticle can render the nanoparticle-containing medium (also referred, to herein as a composite) more transparent to various wavelengths of electromagnetic radiation while imparting thermochromic properties to the nanoparticle-containing medium.

### RELATED APPLICATIONS

This application claims priority under 35 U.S.C. § 119(e) to U.S. Provisional Patent Application No. 63/395,989, filed Aug. 8, 2022, and entitled “Nanoparticle-Containing Media Exhibiting Enhanced Optical Transparency, Related Nanoparticles, and Associated Systems and Methods,” which is incorporated herein by reference in its entirety for all purposes.

### GOVERNMENT SPONSORSHIP

This invention was made with government support under grant number DE-AC02-06CH11357 awarded by the Department of Energy. The government has certain rights in the invention.

### TECHNICAL FIELD

Nanoparticle-containing media exhibiting enhanced optical transparency, related nanoparticles, and associated systems and methods are generally described.

### BACKGROUND

Global energy consumption due to inefficiencies associated with building fenestrations has steadily increased. Per the Department of Energy (DOE), buildings have accounted for the largest fraction of primary energy consumption due to accelerated urbanization, accounting for around 40% of total carbon dioxide (CO₂) emissions in the United States and contributing significantly to global warming and regional climate change. There is a dearth of “smart” technologies that address this issue. Improvements in fenestration materials separating the interiors of buildings from the outside environment could be useful to mitigate solar heat gain during the summertime and to provide desirable heat to building interiors during the wintertime. Currently, some technologies are available that use different chromic materials for “smart” fenestrations. However, in general, their practical applications are hindered by their high production cost and the reduction of visible light transmittance. Thermochromic materials are a better solution for applications as a glazing material because of their temperature-variant properties. Among different thermochromic metal oxides, vanadium oxide (VO₂) has been proposed as a new generation thermochromic material for designing smart windows. VO₂ could allow visible light to transmit but selectively block the near infrared (NIR) solar radiation. VO₂ can transit between the monoclinic (M) semiconducting phase to the rutile (R) metallic phase. Such reversible temperature-induced phase transitions of VO₂ result in a VO₂-based coating capable of modulating the solar radiation in the NIR regime, which contains more than half of the solar radiation energy. One of the drawbacks that has prevented the widespread use of VO₂ is the trade-off between visible light transmittance (VLT) and solar modulation (ΔTsol). A thick VO₂ coating can show high modulation at the expense of its VLT (<40/), mainly because of the high refractive index (RI) of VO₂ (RI ˜3), which results in the scattering of incident light and opaqueness of coatings that incorporate this material.

### SUMMARY

The present disclosure is generally directed to nanoparticle-containing media exhibiting enhanced optical transparency, related nanoparticles, and associated systems and methods. In certain embodiments, the refractive index (RI) of a nanoparticle comprising thermochromic material (such as VO₂) can be made closer to the refractive index of a surrounding medium by tethering a material (such as a gradient copolymer) to the core region of the nanoparticle to modify the refractive index of the nanoparticle. Modifying the refractive index of the nanoparticle to be closer to the refractive index of the medium that contains the nanoparticle can render the nanoparticle-containing medium (also referred to herein as a composite) more transparent to various wavelengths of electromagnetic radiation while imparting thermochromic properties to the nanoparticle-containing medium. The subject matter of the present disclosure involves, in some cases, interrelated products, alternative solutions to a particular problem, and/or a plurality of different uses of one or more systems and/or articles.

In one aspect, nanoparticles are described. In some embodiments, the nanoparticle comprises a core region comprising a thermochromic material; and a shell region around the core region, wherein: a first location within the shell region has a first constructive refractive index with respect to a wavelength of visible electromagnetic radiation at 25° C.; a second location within the shell region that is farther from the core region than the first location within the shell region has a second constructive refractive index with respect to the wavelength of visible electromagnetic radiation at 25° C.; a third location within the shell region that is farther from the core region than the first location and the second location within the shell region has a third constructive refractive index with respect to the wavelength of visible electromagnetic radiation at 25° C.; a fourth location within the shell region that is farther from the core region than the first location, the second location, and the third location within the shell region has a fourth constructive refractive index with respect to the wavelength of visible electromagnetic radiation at 25° C.; the second constructive refractive index is less than or equal to 0.9 times the first constructive refractive index; the third constructive refractive index is less than or equal to 0.9 times the second constructive refractive index; and the fourth constructive refractive index is less than or equal to 0.9 times the third constructive refractive index.

In certain embodiments, the nanoparticle comprises a core region comprising a thermochromic material; and a shell region around the core region, the shell region comprising a polymer, wherein: the core region has a refractive index with respect to at least one wavelength of visible electromagnetic radiation at 25° C.; and the shell region has a refractive index with respect to the wavelength of visible electromagnetic radiation at 25° C. that is less than or equal to 0.9 times the refractive index of the core region.

In certain aspects, collections of nanoparticles are described. In some embodiments, a collection of nanoparticles is provided, wherein each nanoparticle comprises a core region comprising a thermochromic material having a refractive index with respect to a wavelength of visible electromagnetic radiation at 25° C.; and a shell region; and the nanoparticles can be arranged in a matrix material having a refractive index with respect to the wavelength of electromagnetic radiation at 25° C. that is less than or equal to 0.9 times the refractive index of the core region material for that wavelength of electromagnetic radiation at 25° C., such that: when the nanoparticles are evenly distributed within a layer having a thickness of 25 micrometers at 10 wt %, then, at least 50% of the incident visible electromagnetic radiation of the wavelength is transmitted through the layer.

In some aspects, composite materials are provided. In some embodiments, the composite material comprises a matrix material having a refractive index with respect to a wavelength of visible electromagnetic radiation at 25° C.; and nanoparticles dispersed within the matrix material, each of the nanoparticles comprising a thermochromic material having a refractive index with respect to the wavelength of visible electromagnetic radiation at 25° C.; wherein: the refractive index of the matrix material with respect to the wavelength of visible electromagnetic radiation at 25° C. is less than or equal to 0.9 times the refractive index of the thermochromic material with respect to the wavelength of visible electromagnetic radiation at 25° C.; the nanoparticles make up at least 10 wt % of the composite material; and the composite material has a transmittance of the wavelength of visible electromagnetic radiation of at least 50%.

Other advantages and novel features of the present disclosure will become apparent from the following detailed description of various non-limiting embodiments of the disclosure when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present disclosure will be described by way of example with reference to the accompanying figures, which are schematic and are not intended to be drawn to scale unless otherwise indicated. In the figures, each identical or nearly identical component illustrated is typically represented by a single numeral. For purposes of clarity, not every component is labeled in every figure, nor is every component of each embodiment of the disclosure shown where illustration is not necessary to allow those of ordinary skill in the art to understand the disclosure. In the figures:

FIG. 1 is a cross-sectional schematic illustration of a nanoparticle, according to certain embodiments;

FIG. 2 is a cross-sectional schematic illustration of a composite material, according to certain embodiments;

FIGS. 3A-3E are cross-sectional schematic illustrations of a nanoparticle, according to some embodiments;

FIG. 4 shows schematic representations of a gradient copolymer and a block copolymer;

FIG. 5A is a schematic representation of the continuous flow hydrothermal (CFHT) apparatus;

FIG. 5B is a schematic depicting the mechanism behind the VO₂ NPs synthesis process at the reaction zone (violet highlighted area in FIG. 5A);

FIG. 6 is a schematic representation of silica modification of the synthesized VO₂ (M) NPs (VO₂@SiO₂) followed by formation of the core-shelled PMMA-grad-P13FOMA-block-PMOS modified VO₂@SiO₂ NPs (VO₂@SiO₂@GCP) via anchoring of the silatrane moiety on the NPs surface;

FIG. 7 is a synthesis scheme of poly(methyl methacrylate)-grad-poly(1H,1H,2H,2H-perfluorooctyl methacrylate)-block-poly(methacryloxypropylsilatrane) (PMMA-grad-P13FOMA-block-PMOS) via concurrent tandem catalysis, including a metal alkoxide-mediated transesterification of methyl methacrylate (MMA) with 1H,1H,2H,2H-perfluorooctanol (13FOH) and ruthenium-catalyzed living radical polymerization of the respective monomers;

FIGS. 8A-8B are ¹H and ¹⁹F NMR spectra of PMMA-grad-P13FOMA-block-PMOS (GCP 41);

FIG. 8C shows SEC traces of the PMMA-grad-P13FOMA-block-PMOS copolymer with different MMA:13FOOH molar ratios;

FIGS. 9A-9B show SEM images of PMMA-grad-P13FOMA-block-PMOS (GCP 41) modified VO₂@SiO₂NPs (VO₂@SiO₂@GCP 41) (FIG. 9A) and its elemental mapping (FIG. 9B);

FIG. 9C is a TEM image of PMMA-grad-P13FOMA-block-PMOS (GCP 41) modified VO₂@SiO₂ NPs (VO₂@SiO₂@GCP 41) with a zoomed image of the core-shelled structure of the organic-inorganic hybrid NPs;

FIG. 9D is a TEM image of VO₂@SiO₂ NPs;

FIG. 9E is a DLS histogram of PMMA-grad-P13FOMA-block-PMOS (GCP 41) modified VO₂@SiO₂ NPs (VO₂@SiO₂@GCP 41);

FIG. 10 shows images of polymer and composite coated film on quartz cover slip where (thickness ˜2 μm, % loading of NPs 10 wt %);

FIG. 11A is a UV-vis-NIR spectra of the PMMA-grad-P13FOMA-block-PMOS/PMMA-block-P13FOMA-block-PMOS modified VO₂@SiO₂ NPs embedded (VO₂@SiO₂@GCP 41) PMMA nanocomposite films at high temperature (85° C.) and low temperature (32° C.) with NPs loading percentages of 10 wt % at a coating thickness of −25 μm;

FIG. 11B shows a schematic of the variation in copolymer sequence in core-shell VO₂@SiO₂@copolymer NPs and respective alternation in the RI from the core to the shell, measurement of the refractive index (RI) and thickness of the coating;

FIGS. 11C-11D show the obtained ellipsometry results of GCP containing formulations (FIG. 11C) and the BCP containing compositions (FIG. 11D);

FIG. 11E shows that the modification of VO₂@SiO₂ NPs with a precisely designed gradient copolymer improves the clarity of the composite film (% T >90%) containing 10 wt %/ of composite NPs at a thickness of ˜2 μm, compared to the unmodified one (% T<40%);

FIGS. 12A-12B show scaled up fabrication of a composite material comprising the nanoparticles described herein, where coating of VO₂@SiO₂ (FIG. 12A, left image) and VO₂@SiO₂@GCP (FIG. 12B, right image) containing PMMA nanocomposite film was carried out using FOM slot die coater (coating thickness ˜10 μm, % NPs loading 10 wt %);

FIG. 12C is an image of the PMMA+VO₂@SiO₂@GCP 41 nanocomposite film (thickness ˜25 μm, % loading of NPs 10 wt %);

FIG. 12D is a graph showing variation in the water contact angle (WCA) of certain polymers and their composite coated silicon wafer surface;

FIG. 13 shows FTIR spectra of synthesized NPs, gradient polymer, and its nanocomposite;

FIG. 14A shows a SEM image of VO₂ (M) NPs synthesized using continuous flow hydrothermal reactor (CFHT);

FIG. 14B shows a SEM image of silica modified VO₂ NPs (VO₂@SiO₂);

FIG. 14C shows XRD patterns of VO₂ (M), VO₂@SiO₂ and PMMA-grad-P13FOMA-block-PMOS modified VO₂@SiO₂NPs (VO₂@SiO₂@GCP 41);

FIG. 14D shows a DSC thermogram of VO₂ (M) and VO₂@SiO₂ NPs;

FIG. 15 shows a synthesis scheme of poly(methyl methacrylate)-block-poly(1H,1H,2H,2H-perfluorooctyl methacrylate)-block-poly(methacryloxypropyl silatrane) (PMMA-b-P13FOMA-b-PMOS) via sequential RAFT polymerization;

FIGS. 16A-16B are ¹H NMR spectra of PMMA₂₀ (FIG. 16A) and PMMA₂₀-b-P13FOMA (FIG. 16B);

FIG. 17A shows SEC traces of the PMMA₂₀ homopolymer, PMMA₂₀-b-P13FOMA₁₀diblock copolymer, and PMMA₂₀-b-P13FOMA₁₀-b-PMOSstriblock copolymer;

FIGS. 17B-17C show ¹H and ¹⁹F NMR spectra of PMMA₂₀-b-P13FOMA₁₀-b-PMOS₅;

FIG. 18 is a FTIR spectra of the synthesized NPs, gradient polymer and its nanocomposite;

FIGS. 19A-19B show SEM and TEM images of VO₂@SiO₂@BCP NPs respectively;

FIG. 19C shows elemental mapping over the selected area of VO₂@SiO₂@BCP NPs;

FIG. 20 shows a thermogravimetric analysis (TGA) of VO₂@SiO₂ NPs and PMMA-grad-P13FOMA-block-PMOS (GCP 41) coated VO₂@SiO₂ NPs (VO₂@SiO₂@GCP 41);

FIGS. 21A-21B show the determination of RI by varying the thickness of the composite coating (FIG. 21A) and amount of VO₂@SiO₂@GCP 41 loading into the PMMA matrix (FIG. 21B); and

FIGS. 22A-22D show fitting curves obtained from the ellipsometry study of the respective polymer and its composite films.

### DETAILED DESCRIPTION

Disclosed herein are nanoparticle-containing media exhibiting enhanced optical transparency, related nanoparticles, and associated systems and methods. In certain embodiments, the refractive index (RI) of a nanoparticle comprising thermochromic material (such as VO₂) can be made closer to the refractive index of a surrounding medium by tethering a material (such as a gradient copolymer) to the core region of the nanoparticle to modify the refractive index of the nanoparticle. Modifying the refractive index of the nanoparticle to be closer to the refractive index of the medium that contains the nanoparticle can render the nanoparticle-containing medium (also referred to herein as a composite) more transparent to various wavelengths of electromagnetic radiation while imparting thermochromic properties to the nanoparticle-containing medium.

In certain embodiments, nanoparticles with high refractive index (such as VO₂-containing nanoparticles) are cloaked with low refractive index material in a core-shall arrangement (with the core comprising the high RI material and the shell comprising the cloaking material). By adding the shell material to the core, the interface of the nanoparticle and the surrounding medium in which the nanoparticle is dispersed can be made more transparent. The presence of the shell material can reduce the degree to which light is scattered at the interface between the core-shell nanoparticle and the surrounding medium, which can increase the transparency of the composite containing the core-shell nanoparticles and the surrounding medium.

In certain embodiments, the shell region comprises a polymeric material. The use of polymeric materials can allow for a flexible interface between the core region material and the shell region material, relative to the brittle interface that may exist between the core region and the shell region when inflexible materials such as metal oxides and/or ceramics are used in both the core region and the shell region. In some embodiments, the shell region comprises a gradient copolymer. The use of gradient copolymer in the shell region has been found, unexpectedly, to increase the transparency of the nanoparticles when they are embedded in certain matrix materials, relative to other types of polymers, such as block copolymers. The shell material can be arranged such that the constructive refractive index (described in more detail elsewhere herein) is lowered from the exterior of the core region to the exterior of the shell region.

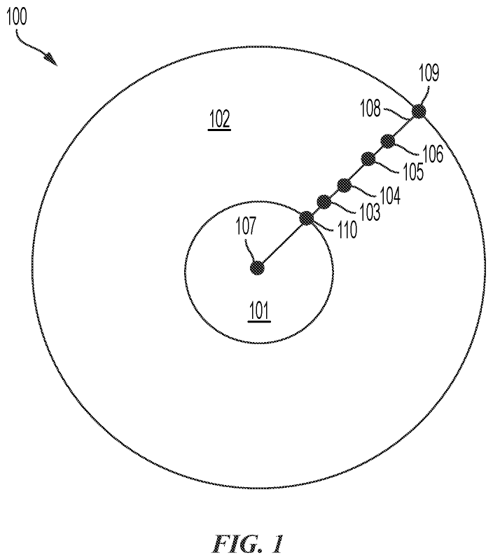

As noted above, in certain aspects, nanoparticles are provided. FIG. 1 is a cross-sectional schematic illustration of a nanoparticle 100 according to certain embodiments. Generally, a nanoparticle is a particle that has a maximum cross-sectional dimension of less than 1 micrometer. The “maximum cross-sectional dimension” of a structure, as used herein, refers to the longest distance between two opposed boundaries of that structure that passes through the geometric center of that structure. In the case of a particle that is in the shape of a perfect sphere, for example, the maximum cross-sectional dimension of the particle would be the diameter of the particle.

In some embodiments, the nanoparticles have a maximum cross-sectional dimension of less than or equal to 900 nanometers (nm), less than or equal to 800 nanometers, less than or equal to 700 nanometers, less than or equal to 600 nanometers, less than or equal to 500 nanometers, less than or equal to 400 nanometers, less than or equal to 300 nanometers, less than or equal to 200 nanometers, less than or equal to 100 nanometers, less than or equal to 50 nanometers, or less. In some embodiments, the nanoparticles have a maximum cross-sectional dimension of greater than or equal to 10 nanometers, greater than or equal to 25 nanometers, greater than or equal to 50 nanometers, greater than or equal to 100 nanometers, greater than or equal to 200 nanometers, greater than or equal to 300 nanometers, or more. Combinations of these ranges are also possible (e.g., greater than or equal to 50 nanometers and less than or equal to 1 micrometer). Other ranges are also possible. In certain embodiments in which a plurality of nanoparticles is present as a collection and/or is present within a composite material (embodiments of which are described in more detail below), at least 50 wt %, at least 75 wt %, at least 90 wt %, at least 95 wt %, at least 98 wt %, at least 99 wt %, or more (e.g., up to 100 wt/o) of the nanoparticles within the plurality of nanoparticles can have a cross-sectional dimension within these ranges.

In some embodiments, the nanoparticles can be relatively highly equiaxed. That is to say, in some embodiments, the ratio of the maximum cross-sectional dimension of the nanoparticles to the minimum cross-sectional dimension of the nanoparticles can be relatively close to 1. The “minimum cross-sectional dimension” of a structure, as used herein, refers to the smallest distance between two opposed boundaries of that structure that passes through the geometric center of that structure. In the case of a particle that is in the shape of a perfect sphere, both the maximum cross-sectional dimension of the particle and the minimum cross-sectional dimension of the particle would correspond to the diameter of the particle.

In some embodiments, the nanoparticles can be shaped such that the ratio of the maximum cross-sectional dimension to the minimum cross-sectional dimension is less than or equal to 2, less than or equal to 1.75, less than or equal to 1.5, less than or equal to 1.4, less than or equal to 1.3, less than or equal to 1.2, less than or equal to 1.1, less than or equal to 1.05, less than or equal to 1.02, or less (and/or, in some embodiments, as little as 1.01, or as little as 1). A ratio of A to B, when expressed in decimal form (as is done above for the ratio of the maximum cross-sectional dimension to the minimum cross-sectional dimension), is calculated by dividing the value of A by the value of B. In certain embodiments in which a plurality of nanoparticles is present as a collection and/or is present within a composite material, at least 50 wt %, at least 75 wt %, at least 90 wt %, at least 95 wt %, at least 98 wt %, at least 99 wt %, or more (e.g., up to 100 wt %) of the nanoparticles within the plurality of nanoparticles can have ratios of maximum-cross sectional dimension to minimum cross-sectional dimension within these ranges.

The nanoparticle comprises, in some embodiments, a core region. For example, referring to FIG. 1, nanoparticle 100 comprises core region 101. In some embodiments, the core region itself is formed by forming a nanoparticle. Examples of fabrication techniques for such nanoparticles can be found, for example, in U.S. Pat. No. 9,975,804 B2, issued on May 22, 2018, and entitled “Continuous Flow Synthesis of VO₂ Nanoparticles or Nanorods by Using a Microreactor,” which is incorporated herein by reference in its entirety for all purposes.

The core region can have any of a variety of suitable sizes. In some embodiments, the maximum cross-sectional dimension of the core region is less than or equal to 950 nanometers, less than or equal to 900 nanometers, less than or equal to 800 nanometers, less than or equal to 700 nanometers, less than or equal to 600 nanometers, less than or equal to 500 nanometers, less than or equal to 400 nanometers, less than or equal to 300 nanometers, less than or equal to 200 nanometers, less than or equal to 100 nanometers, less than or equal to 50 nanometers, or less. In some embodiments, the maximum cross-sectional dimension of the core region is greater than or equal to 5 nanometers, greater than or equal to 10 nanometers, greater than or equal to 25 nanometers, greater than or equal to 50 nanometers, greater than or equal to 100 nanometers, greater than or equal to 200 nanometers, greater than or equal to 300 nanometers, or more. Combinations of these ranges are also possible (e.g., greater than or equal to 5 nanometers and less than or equal to 950 nanometers). Other ranges are also possible. In certain embodiments in which a plurality of nanoparticles is present as a collection and/or is present within a composite material, at least 50 wt %, at least 75 wt %, at least 90 wt %, at least 95 wt %, at least 98 wt %, at least 99 wt %, or more (e.g., up to 100 wt %) of the nanoparticles within the plurality of nanoparticles can comprise core regions having maximum cross-sectional dimensions within these ranges.

In some embodiments, the core region is made of a single material (e.g., VO₂). In other embodiments, the core region comprises more than one material (e.g., VO₂ and another metal oxide or a metalloid oxide, such as SiO₂).

In some embodiments, the core region comprises a thermochromic material. The thermochromic material may comprise any of a variety of one or more materials, including any suitable thermochromic material known in the art, non-limiting examples of which are discussed in further detail below. In certain embodiments, a relatively large percentage of the core region can be made of thermochromic material. For example, in some embodiments, at least 25 weight percent (wt %), at least 30 wt %, at least 40 wt %, at least 50 wt %, at least 60 wt %, at least 70 wt %, at least 80 wt %, or more of the core region is made of thermochromic material (e.g., any one or more of the thermochromic materials listed elsewhere herein). In some embodiments, less than or equal to 100 wt %, less than or equal to 99 wt %, less than or equal to 98 wt %, less than or equal to 95 wt %, less than or equal to 90 wt %, less than or equal to 80 wt %, or less of the core region is made of thermochromic material. Combinations of these ranges are also possible (e.g., at least 25 wt/o and less than or equal to 100 wt %). Other ranges are also possible.

The core region can be porous or non-porous. In some embodiments, a relatively large percentage of the volume of the core region is made of solid material (e.g., one or more solid thermochromic materials). For example, in some embodiments, at least 25 wt %, at least 30 wt %, at least 40 wt %, at least 50 wt %, at least 60 wt %, at least 70 wt %, at least 80 wt %, at least 90 wt %, at least 95 wt %, at least 99 wt %, or more of the core region is made of solid material. In some embodiments, less than or equal to 100 wt %, less than or equal to 99 wt %, less than or equal to 98 wt %, less than or equal to 95 wt %, or less of the core region is made of solid material. Combinations of these ranges are also possible (e.g., at least 25 wt % and less than or equal to 100 wt %). Other ranges are also possible.

The nanoparticle comprises, in some embodiments, a shell region around the core region. Referring to FIG. 1, for example, nanoparticle 100 comprises shell region 102, which surrounds core region 101.

The shell region can have any of a variety of suitable thicknesses. Generally, the thickness of the shell region corresponds to the length of a line segment beginning at a location at the exterior of the core region and extending in a direction outward from the geometric center of the core region to a location on the exterior of the shell region. For example, referring to FIG. 1, nanoparticle 100 comprises a shell region 102, which surrounds the core region 101, wherein the thickness of the shell region is equivalent to a line segment beginning at a location 110 at the exterior of the core region and extending in a direction outward from the core region to a location 109 on the exterior of the shell region.

In some embodiments, the thickness of the shell region is at least 50 nanometers, at least 100 nanometers, at least 200 nanometers, at least 300 nanometers, or more. In some embodiments, the thickness of the shell region is less than or equal to 950 nanometers, less than or equal to 900 nanometers, less than or equal to 800 nanometers, less than or equal to 700 nanometers, less than or equal to 600 nanometers, less than or equal to 500 nanometers, less than or equal to 400 nanometers, less than or equal to 300 nanometers, less than or equal to 200 nanometers, less than or equal to 100 nanometers, or less. Combinations of these ranges are also possible (e.g., at least 50 nanometers and less than or equal to 950 nanometers). Other ranges are also possible. In certain embodiments in which a plurality of nanoparticles is present as a collection and/or is present within a composite material, at least 50 wt %, at least 75 wt %, at least 90 wt %, at least 95 wt %, at least 98 wt %, at least 99 wt %, or more (e.g., up to 100 wt %) of the nanoparticles within the plurality of nanoparticles can comprise shell regions having thicknesses within these ranges.

In some embodiments, the shell region is made of a single material (e.g., a polymer such as a gradient copolymer). In other embodiments, the shell region comprises more than one material.

In certain embodiments, the shell region comprises material that is organic. In some embodiments, the shell material contains material that is flexible. The use of flexible materials (such as organic polymers and other types of flexible materials) in the shell can lead to the formation of a core-shell interface that is more mechanically robust than the core-shell interface would be if brittle materials (e.g., inorganic materials such as metal/metalloid oxides, metal/metalloid nitrides, ceramics, and the like) were employed.

In some embodiments, the material of the shell has a Young's Modulus (as measured using ASTM Test Method D638-14) of less than or equal to 60 GPa, less than or equal to 40 GPa, less than or equal to 10 GPa, less than or equal to 5 GPa, or less than or equal to 3 GPa (and/or, in some embodiments, greater than or equal to 0.00001 GPa, greater than or equal to 0.0001 GPa, greater than or equal to 0.001 GPa, greater than or equal to 0.01 GPa, greater than or equal to 0.1 GPa, or greater than or equal to 1 GPa). Other ranges are also possible.

In some embodiments, the material of the shell has an elongation at break (as measured using ASTM Test Method D638-14) of greater than or equal to 0.01%, greater than or equal to 0.05%, greater than or equal to 0.1%, greater than or equal to 0.5%, greater than or equal to 1%, greater than or equal to 1.5%, greater than or equal to 2%, greater than or equal to 2.5%, greater than or equal to 3%, greater than or equal to 5%, greater than or equal to 10%, or more (and/or, in some embodiments, less than or equal to 5000%, less than or equal to 2000%, less than or equal to 1000%, less than or equal to 500%, less than or equal to 100%, less than or equal to 10%, or less.) Other ranges are also possible.

In some embodiments, the material of the shell has a flexural modulus (as measured using ASTM Test Method D790-10) of greater than or equal to 0.01 MPa, greater than or equal to 0.1 MPa, greater than or equal to 1 MPa, greater than or equal to 10 MPa, greater than or equal to 50 MPa, greater than or equal to 100 MPa, greater than or equal to 500 MPa, greater than or equal to 1 GPa, or greater than or equal to 2 GPa (and/or, in some embodiments, less than or equal to 100 GPa, less than or equal to 10 GPa, or less than or equal to 5 GPa). Other ranges are also possible.

In some embodiments, the material of the shell has a flexural strength (as measured using ASTM Test Method D790-10) of greater than or equal to 0.01 MPa, greater than or equal to 0.1 MPa, greater than or equal to 1 MPa, greater than or equal to 10 MPa, greater than or equal to 50 MPa, or greater than or equal to 100 MPa (and/or, in some embodiments, less than or equal to 10 GPa, less than or equal to 1 GPa, less than or equal to 500 MPa, or less than or equal to 300 MPa). Other ranges are also possible.

In some embodiments, the shell region comprises at least one polymer. The polymer material will generally comprise at least one monomer moiety. A monomer moiety is a moiety within a polymer that results from polymerization of a monomer. In some embodiments, the number average molecular weight of the polymer material in the shell can be at least 5000 g/mol; at least 10,000 g/mol; at least 20,000 g/mol; or at least 30,000 g/mol (and/or, in some embodiments, less than or equal to 100,000 g/mol; less than or equal to 75,000 g/mol; less than or equal to 50,000 g/mol; or less than or equal to 35,000 g/mol.

As noted above, the use of polymer material in the shell region can impart flexibility between the interface of the core region and the shell region.

In some embodiments, the shell region comprises a copolymer. Copolymers are polymers that contain more than one type of monomer moiety (e.g., at least 2 types of monomer moieties, at least 3 types of monomer moieties, etc.). The copolymer may comprise any of a variety of materials, non-limiting examples of which are described in further detail below.

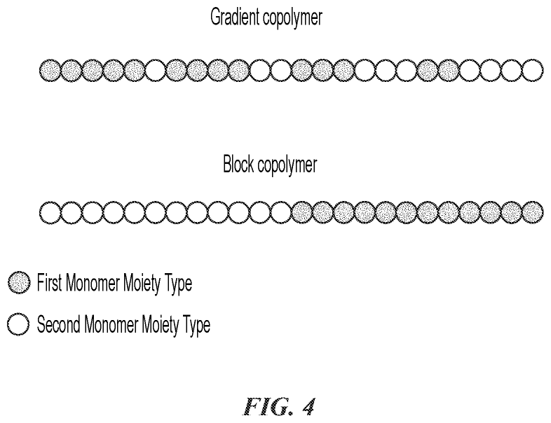

In some embodiments, the shell region comprises a gradient copolymer. A gradient copolymer is a copolymer comprising at least a first monomer moiety and a second monomer moiety, in which the change in monomer composition is gradual from predominantly the first monomer moiety to predominantly the second monomer moiety. For example, referring to FIG. 4, the gradient copolymer (top of FIG. 4) comprises a first monomer moiety and a second monomer moiety, wherein the monomer composition, from left to right, changes gradually from predominantly the first monomer to predominantly the second monomer. In contrast, the block copolymer (bottom of FIG. 4) switches consistently at regular intervals from first monomer moiety to second monomer moiety. In some embodiments, at least 50 wt %, at least 75 wt %, at least 90 wt %, at least 95 wt %, or more of the polymer in the shell region is in the form of a gradient copolymer.

In some embodiments in which a polymer (e.g., a gradient copolymer) is used in the shell region, the polymer extends in a direction outward from the core region to an exterior of the shell region. For example, referring to FIG. 1, in some embodiments, the polymer extends in a direction starting at location 110 and ending at location 109. The direction in which a polymer extends can be determined by tracing a pathway along the backbone of the polymer.

In some embodiments, the shell region comprises a block copolymer. A block copolymer is a copolymer comprised of at least a first monomer moiety and at least a second monomer moiety in which the change in monomer composition is abrupt from the first monomer to the second monomer. For example, referring to FIG. 4, the block copolymer is comprised of a first monomer moiety and a second monomer moiety in which the change in monomer composition from the first monomer to the second monomer is abrupt.

In some embodiments, the shell region comprises a polymer comprising at least a first monomer moiety, at least a second monomer moiety, and at least a third monomer moiety, wherein the monomer composition may form a gradient copolymer, block copolymer, or a combination gradient and block copolymer. For example, in some embodiments, a first section of the polymer (which may make up at least 50 wt %, at least 75 wt %, at least 90 wt %, at least 95 wt %, or more of the polymer) is a gradient copolymer and a second section of the polymer is a block copolymer.

In some embodiments, the shell region comprises a polymer (e.g., a gradient copolymer or other copolymer) extending in a direction outward from the core region to an exterior of the shell region. In some embodiments, the polymer is tethered to the core region via a linker moiety. The linker moiety may comprise any of a variety of materials, non-limiting examples of which are discussed in further detail below.

In certain embodiments, a relatively large percentage of the shell region can be made of polymeric material (e.g., organic polymer material and/or gradient copolymer). For example, in some embodiments, at least 25 weight percent (wt %), at least 30 wt %, at least 40 wt %, at least 50 wt %, at least 60 wt %, at least 70 wt %, at least 80 wt %, or more of the core region is made of polymeric material (e.g., organic polymer and/or gradient copolymer, including any one or more of the polymeric materials listed elsewhere herein). In some embodiments, less than or equal to 100 wt %, less than or equal to 99 wt %, less than or equal to 98 wt %, less than or equal to 95 wt %, less than or equal to 90 wt %, less than or equal to 80 wt %, or less of the core region is made of polymeric material. Combinations of these ranges are also possible (e.g., at least 25 wt % and less than or equal to 100 wt %). Other ranges are also possible.

In certain embodiments, a relatively large percentage of the shell region can be made of organic material (e.g., organic polymer material and/or gradient copolymer). For example, in some embodiments, at least 25 weight percent (wt %), at least 30 wt %, at least 40 wt %, at least 50 wt %, at least 60 wt %, at least 70 wt %, at least 80 wt %, or more of the core region is made of organic material (e.g., organic polymer and/or gradient copolymer, including any one or more of the polymeric materials listed elsewhere herein). In some embodiments, less than or equal to 100 wt %, less than or equal to 99 wt %, less than or equal to 98 wt %, less than or equal to 95 wt %, less than or equal to 90 wt %, less than or equal to 80 wt %, or less of the core region is made of organic material. Combinations of these ranges are also possible (e.g., at least 25 wt/o and less than or equal to 100 wt %). Other ranges are also possible.

The shell region can be porous or non-porous. In some embodiments, a relatively large percentage of the volume of the shell region is made of solid material (e.g., one or more solid polymeric materials). For example, in some embodiments, at least 25 wt %, at least 30 wt %, at least 40 wt %, at least 50 wt %, at least 60 wt %, at least 70 wt %, at least 80 wt %, at least 90 wt %, at least 95 wt %, at least 99 wt %, or more of the shell region is made of solid material. In some embodiments, less than or equal to 100 wt %, less than or equal to 99 wt %, less than or equal to 98 wt %, less than or equal to 95 wt %, or less of the shell region is made of solid material. Combinations of these ranges are also possible (e.g., at least 25 wt/o and less than or equal to 100 wt/o). Other ranges are also possible.

In certain aspects, collections of nanoparticles are described (e.g.., within a matrix, suspension, or any other form). The nanoparticles within the collection can each have the properties described above and elsewhere herein with respect to individual nanoparticles. In some embodiments, the nanoparticles within the collection can be loose nanoparticles, individually manipulatable and discrete from one another.

In some embodiments, the nanoparticles within the collection may be substantially the same shape and/or size.

In some embodiments, the nanoparticles within the collection have a distribution of sizes such that the standard deviation of the maximum cross-sectional dimensions of the nanoparticles is no more than 100%, no more than 50%, no more than 25%, no more than 10%, no more than 5%, no more than 2%, or no more than 1% of the arithmetic average of the maximum cross-sectional dimensions of the nanoparticles. The “arithmetic average” (also known as the arithmetic mean) of a series of values is calculated by dividing the sum of all of the values in the series by the number of values in the series. For a collection of nanoparticles, the arithmetic average of the maximum cross-sectional dimensions of the nanoparticles (D_{avg}) would be calculated as:

$${D}_{avg} = \frac{{\sum }_{i = 1}^{n} {D}_{i}}{n}$$

where n is the number of nanoparticles in the collection, and DA is the maximum cross-sectional dimension of nanoparticle i in the collection. The standard deviation of the maximum cross-sectional dimensions of the nanoparticles within a collection (σ_{Dmax}) is calculated as:

$${σ}_{Dmax} = \sqrt{\frac{{\sum }_{i = 1}^{n} {( {D}_{i} - {D}_{avg} )}^{2}}{n - 1}}$$

where Dᵢ is, again, the maximum cross-sectional dimension of nanoparticle i in the collection; D_{avg} is, again, the arithmetic average of the maximum cross-sectional dimensions of the nanoparticles in the collection; and n is, again, the number of nanoparticles in the collection. Percentage comparisons between the standard deviation and the arithmetic average can be obtained by dividing the standard deviation by the arithmetic average and multiplying by 100%.

In some embodiments, the nanoparticles within the collection have a distribution of ratios of maximum cross-sectional dimension to minimum cross-sectional dimension such that the standard deviation of the ratios of maximum cross-sectional dimension to minimum cross-sectional dimension is no more than 100%, no more than 50%, no more than 25%, no more than 10%, no more than 5%, no more than 2%, or no more than 1% of the arithmetic average of the ratios of maximum cross-sectional dimension to minimum cross-sectional dimension. The arithmetic average of the ratios of the maximum cross-sectional dimension to minimum cross-sectional dimension for a collection of nanoparticles (DimRatio_{avg}) is calculated as:

$${DimRatio}_{avg} = \frac{{\sum }_{i = 1}^{n} {R}_{i}}{n}$$

where n is the number of nanoparticles in the collection, and Rᵢ is the ratio of the maximum cross-sectional dimension of nanoparticle i in the collection to the minimum cross-sectional dimension of nanoparticle i in the collection. The standard deviation of the ratios of maximum cross-sectional dimension to minimum cross-sectional dimension for a collection of nanoparticles (σ_{Dmax}) is calculated as:

$${σ}_{DimRatio} = \sqrt{\frac{{\sum }_{i = 1}^{n} {( {R}_{i} - {DimRatio}_{avg} )}^{2}}{n - 1}}$$

where Rᵢ is, again, the ratio of the maximum cross-sectional dimension of nanoparticle i in the collection to the minimum cross-sectional dimension of nanoparticle i in the collection; DimRatio_{avg} is, again, the arithmetic average of the ratios of the maximum cross-sectional dimension to minimum cross-sectional dimension for the collection; and n is, again, the number of nanoparticles in the collection. As noted above, the percentage comparisons between the standard deviation and the arithmetic average outlined above can be obtained by dividing the standard deviation by the arithmetic average and multiplying by 100%.

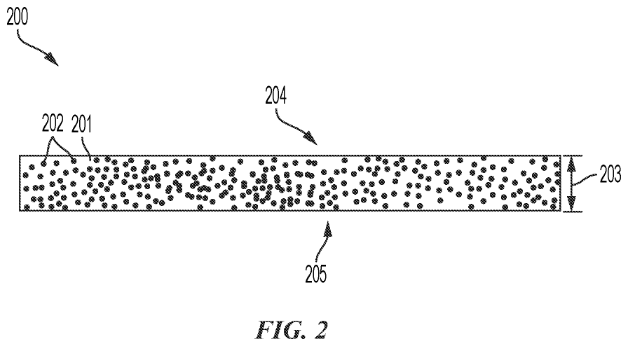

In some embodiments, the collection of nanoparticles can be arranged in a matrix material. For example, referring to FIG. 2, the collection of nanoparticles 202 is arranged in matrix material 201 to form composite material 200.

In certain embodiments, the nanoparticles within the collection can be configured such that, for at least one matrix material having a smaller index of refraction than the thermochromic material in the nanoparticle, the nanoparticles can be embedded in the matrix material to a relatively high degree with only a limited impact on transparency of the composite.

For example, in certain embodiments, the nanoparticles within the collection can be configured such that there is at least one matrix material having a refractive index with respect to at least one wavelength of visible electromagnetic radiation (e.g.. 633 nanometers or any other wavelength of visible electromagnetic radiation) at 25° C. that is less than or equal to 0.9 times (or less than or equal to 0.8 times, less than or equal to 0.7 times, less than or equal to 0.6 times, less than or equal to 0.5 times, or less than or equal to 0.4 times) the refractive index of the thermochromic material in the core regions of the nanoparticles for that wavelength of visible electromagnetic radiation at 25° C., and such that when the nanoparticles are evenly distributed in an amount of 10 wt % in a layer of the matrix material having a thickness of 25 micrometers, then at least 50% (or at least 60%, at least 70%, and/or up to 75%, up to 80%, up to 90°/%, or up to 100%) of that wavelength of visible electromagnetic radiation that is incident on a major surface of the layer is transmitted through the layer.

In certain embodiments, the nanoparticles within the collection can be configured such that there is at least one matrix material having refractive indices for at least 25% (or at least 50%, at least 75%, at least 90%, at least 95%, at least 99%, or up to 100%) of all wavelengths of visible electromagnetic radiation at 25° C. that are less than or equal to 0.9 times (or less than or equal to 0.8 times, less than or equal to 0.7 times, less than or equal to 0.6 times, less than or equal to 0.5 times, or less than or equal to 0.4 times) the corresponding refractive indices of the thermochromic material in the core regions of the nanoparticles, and such that when the nanoparticles are evenly distributed in an amount of 10 wt % in a layer of the matrix material having a thickness of 25 micrometers, then at least 50% (or at least 60%, at least 70%, and/or up to 75%, up to 80%, up to 90%, or up to 100%) of those wavelengths of visible electromagnetic radiation that are incident on a major surface of the layer are transmitted through the layer.

A “corresponding” refractive index is a refractive index measured at a particular wavelength and temperature. For example, if Material A has a refractive index with respect to 633 nanometers at 25° C., the “corresponding” refractive index of Material B would be the refractive index of Material B at 633 nanometers and 25° C.

In certain embodiments, the collection of nanoparticles can be configured such that they are capable of creating any of the composite materials (e.g., the composite materials comprising the collection of nanoparticles and a matrix material) described below or elsewhere herein.

As noted above, in certain embodiments, the refractive index of the nanoparticles (or portions thereof) can be configured to enhance the degree to which the nanoparticles can be cloaked in matrix materials. The refractive index (also referred to as the index of refraction) of a material medium relates the speed of light in vacuum to the speed of light in that material medium, and is calculated as follows:

$$n = \frac{c}{v}$$

where n is the refractive index of a material, c is the speed of light in vacuum, and v is the speed of light in the material for which the refractive index is being determined. The refractive index is a dimensionless number that provides an indication of the light bending ability of a particular material. The refractive index of a material is an intrinsic property of the material. Those of ordinary skill in the art are familiar with techniques that can be used to measure the refractive index of a material, such as ellipsometry.

In some embodiments, it can be advantageous to configure the shell region of the nanoparticle such that the shell region has a smaller refractive index than the core region of the nanoparticle. Configuring the nanoparticle in this way can allow one, in accordance with certain embodiments, to disperse the nanoparticle in a matrix material having a lower refractive index than the material within the core region while maintaining the transparency of the overall matrix/nanoparticle composite.

Accordingly, in some embodiments, the core region has a refractive index with respect to at least one wavelength of visible electromagnetic radiation (e.g., a wavelength of 633 nanometers and/or any other wavelength of visible electromagnetic radiation) at 25° C., and the shell region has a refractive index with respect to the wavelength of visible electromagnetic radiation at 25° C. that is less than or equal to 0.9 times (or less than or equal to 0.8 times, less than or equal to 0.7 times, less than or equal to 0.6 times, less than or equal to 0.5 times, less than or equal to 0.4 times, less than or equal to 0.3 times, less than or equal to 0.2 times, and/or as little as 0.1 times or as little as 0.01 times, or less) the refractive index of the core region. The refractive index of the core region can be determined by performing ellipsometry on bulk material that is made of the same material as the core region. Similarly, the refractive index of the shell region can be determined by performing ellipsometry on bulk material that is made of the same material as the shell region.

As used herein, “visible” electromagnetic radiation means electromagnetic radiation having a wavelength of from 400 nm to 700 nm.

In some embodiments, for at least 25%, at least 50%, at least 75%, at least 90%, at least 95%, at least 98%, or at least 99% (and/or, up to 100%) of the wavelengths of visible electromagnetic radiation, the refractive index of the shell region at 25° C. is less than or equal to 0.9 times, less than or equal to 0.8 times, less than or equal to 0.7 times, less than or equal to 0.6 times, less than or equal to 0.5 times, less than or equal to 0.4 times, less than or equal to 0.3 times, less than or equal to 0.2 times, and/or as little as 0.1 times, or as little as 0.01 times (or less) the refractive index of the core region at 25° C.

In some embodiments, for at least one wavelength of visible electromagnetic radiation (e.g., at 633 nm, or for at least 25%, at least 50%, at least 75%, at least 90%, at least 95%, at least 98%, or at least 99%, and/or up to 100% of the wavelengths of visible electromagnetic radiation), the refractive index of the shell region at 25° C. is less than or equal to 0.9 times, less than or equal to 0.8 times, less than or equal to 0.7 times, less than or equal to 0.6 times, less than or equal to 0.5 times, less than or equal to 0.4 times, less than or equal to 0.3 times, less than or equal to 0.2 times, and/or as little as 0.1 times, or as little as 0.01 times (or less) the refractive index of the thermochromic material in the core region at 25° C.

In some embodiments, for at least one wavelength of visible electromagnetic radiation (e.g., at 633 nm, or for at least 25%, at least 50%, at least 75%, at least 90%, at least 95%, at least 98%, or at least 99%, and/or up to 100% of the wavelengths of visible electromagnetic radiation), the refractive index of the polymeric material in the shell region (e.g., the gradient copolymer material in the shell region) at 25° C. is less than or equal to 0.9 times, less than or equal to 0.8 times, less than or equal to 0.7 times, less than or equal to 0.6 times, less than or equal to 0.5 times, less than or equal to 0.4 times, less than or equal to 0.3 times, less than or equal to 0.2 times, and/or as little as 0.1 times, or as little as 0.01 times (or less) the refractive index of the thermochromic material in the core region at 25° C.

In some embodiments, the constructive refractive index at a specific location within an article is described. As used herein, the “constructive refractive index” (or, equivalently, the “constructive index of refraction”) refers to the refractive index at a specific location within an article, and it is determined by determining the refractive index of a hypothetical article that would consist of all material of the article that exists within the smallest volumetric inner percentage of the article that includes the specific location of the article for which the constructive refractive index is being measured. The volumetric inner percentage is generally expressed as a number (e.g., the “inner 90 vol %,” the “inner 50 vol %”, etc.) and it consists of the sub-volume of the article that is made up of the geometric center of the article and all points occupied by all line segments that begin at the geometric center of the article and extend a distance that is the specified percentage of the way to the outer boundary of the article. To illustrate, the “inner 90 vol %” of an article consists of the sub-volume of the article that is made up of the geometric center of the article and all points occupied by all line segments that begin at the geometric center of the article and extend a distance that is 90% of the way to the outer boundary of the article. Similarly, the “inner 20 vol %” of the article consists of the sub-volume of the article that is made up of the geometric center of the article and all points occupied by all line segments that begin at the geometric center of the article and extend a distance that is 20% of the way to the outer boundary of the article. Such sub-volumes of the article will have the same shape as the overall article, but will be smaller in size. For a spherical particle, the “inner X %” of the spherical particle would correspond to a sphere having a radius that is X % of the radius of the spherical particle.

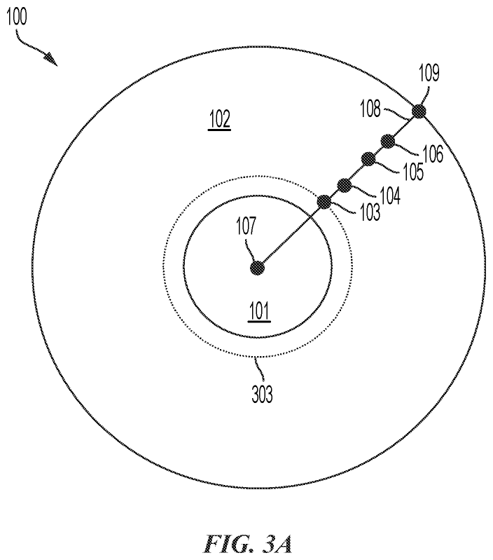

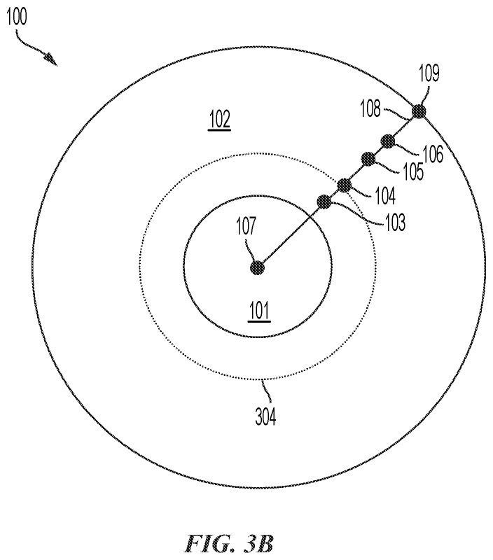

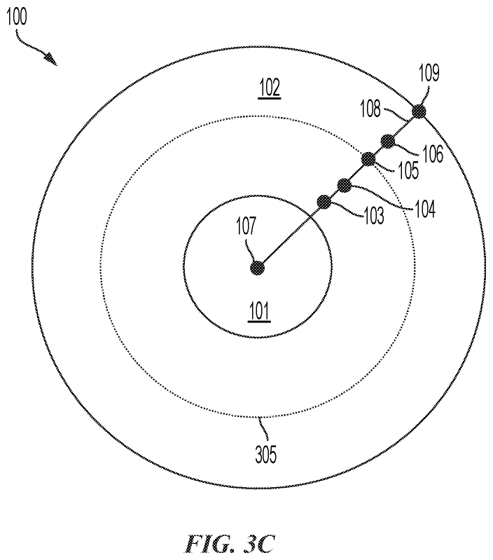

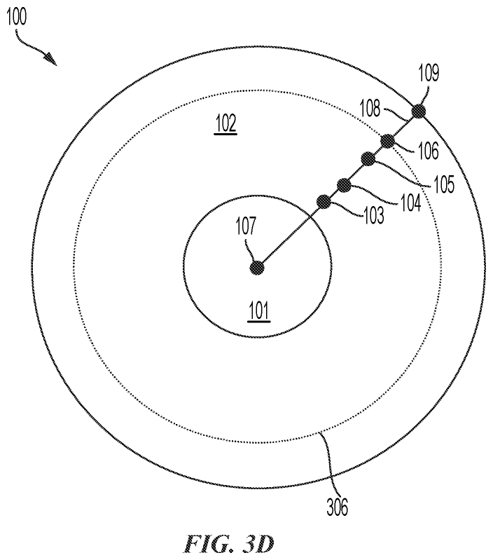

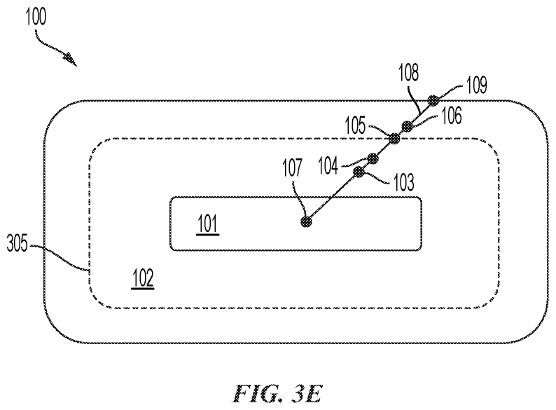

To illustrate, referring to FIG. 3A, the constructive refractive index at location 103 in nanoparticle 100 would be determined by determining the refractive index of an article consisting of all material within volume 303 (i.e., within the dashed line in FIG. 3A), since volume 303 consists of all material of nanoparticle 100 that exists within the smallest volumetric inner percentage of nanoparticle 100 that includes location 103. To illustrate further, referring to FIG. 3B, the constructive refractive index at location 104 in nanoparticle 100 would be determined by determining the refractive index of an article consisting of all material within volume 304 (i.e., within the dashed line in FIG. 3B) since volume 304 consists of all material of nanoparticle 100 that exists within the smallest volumetric inner percentage of nanoparticle 100 that includes location 104. To illustrate even further, referring to FIG. 3C, the constructive refractive index at location 105 in nanoparticle 100 would be determined by determining the refractive index of an article consisting of all material within volume 305 (i.e., within the dashed line in FIG. 3C), since volume 305 consists of all material of nanoparticle 100 that exists within the smallest volumetric inner percentage of nanoparticle 100 that includes location 105. Finally, to illustrate using FIG. 3D, the constructive refractive index at location 106 in nanoparticle 100 would be determined by determining the refractive index of an article consisting of all material within volume 306 (i.e., within the dashed line in FIG. 3D), since volume 306 consists of all material of nanoparticle 100 that exists within the smallest volumetric inner percentage of nanoparticle 100 that includes location 106. The constructive refractive index at all points along the outer surface of the nanoparticle would correspond to the actual refractive index of the nanoparticle.

The concept of constructive refractive index also applies to particles having shapes other than spheres. Referring to FIG. 3E, for example, the constructive refractive index at location 105 in nanoparticle 100 would be determined by determining the refractive index of an article consisting of all material within volume 305 (i.e., within the dashed line in FIG. 3E), since volume 305 consists of all material of nanoparticle 100 that exists within the smallest volumetric inner percentage of nanoparticle 100 that includes location 105.

In certain embodiments, the nanoparticle comprises multiple regions having constructive refractive indices that decrease in a direction extending from the geometric center of the nanoparticle to the external surface of the nanoparticle. The use of such particles has been found, unexpectedly, to enhance the degree to which the nanoparticles can be cloaked in a surrounding matrix material.

For example, in some embodiments, a first location within the shell region has a first constructive refractive index with respect to a wavelength of visible electromagnetic radiation (e.g., a wavelength of 633 nanometers and/or any other wavelength of visible electromagnetic radiation) at 25° C.; a second location within the shell region that is farther from the core region than the first location within the shell region has a second constructive refractive index with respect to the wavelength of visible electromagnetic radiation at 25° C.; a third location within the shell region that is farther from the core region than the first location and the second location within the shell region has a third constructive refractive index with respect to the wavelength of visible electromagnetic radiation at 25° C.; and a fourth location within the shell region that is farther from the core region than the first location, the second location, and the third location within the shell region has a fourth constructive refractive index with respect to the wavelength of visible electromagnetic radiation at 25° C. In some such embodiments, the second constructive refractive index is less than or equal to 0.9 times the first constructive refractive index; the third constructive refractive index is less than or equal to 0.9 times the second constructive refractive index; and the fourth constructive refractive index is less than or equal to 0.9 times the third constructive refractive index. To illustrate, referring to FIG. 1, in some embodiments, first location 103 within shell region 102 has a first constructive refractive index with respect to a wavelength of visible electromagnetic radiation at 25° C.; second location 104 within shell region 102 (which is farther from core region 101 than first location 103) has a second constructive refractive index with respect to the wavelength of visible electromagnetic radiation at 25° C.; third location 105 within shell region 102 (which is farther from core region 101 than first location 103 and second location 104) has a third constructive refractive index with respect to the wavelength of visible electromagnetic radiation at 25° C.; and fourth location 106 within shell region 102 (which is farther from core region 101 than first location 103, second location 104, and third location 105) has a fourth constructive refractive index with respect to the wavelength of visible electromagnetic radiation at 25° C. In some such embodiments, the constructive refractive index at location 104 is less than or equal to 0.9 times the constructive refractive index at location 103: the constructive refractive index at location 105 is less than or equal to 0.9 times the constructive refractive index at location 104; and the constructive refractive index at location 106 is less than or equal to 0.9 times the constructive refractive index at location 105. In some embodiments, for at least 25%, at least 50%, at least 75%, at least 90%, at least 95%, at least 98%, or at least 99% (and/or, up to 100%) of the wavelengths of visible electromagnetic radiation, the constructive refractive indices at the second location are less than or equal to 0.9 times the corresponding constructive refractive indices at the first location; the constructive refractive indices at the third location are less than or equal to 0.9 times the corresponding constructive refractive indices at the second location; and the constructive refractive indices at the fourth location are less than or equal to 0.9 times the corresponding constructive refractive indices at the third location.

In certain embodiments, over at least 50% (or over at least 75%, at least 90%, at least 95%, or more (e.g., up to 100%)) of the distance through the shell region, in a direction from an exterior of the core region to an exterior of the shell region, and following a line segment that begins at the geometric center of the nanoparticle and extends outward to the exterior of the shell region, the constructive refractive index of the shell region is decreasing. For example, referring to FIG. 1, in some embodiments, over at least 50% (or over at least 75%, at least 90%, at least 95%, or more (e.g., up to 100%)) of the distance through shell region 102, in a direction from exterior 110 of core region 101 to exterior 109 of shell region 102, and following line segment 108 (which begins at geometric center 107 of nanoparticle 100 and extends outward to exterior 109 of shell region 102), the constructive refractive index of the shell region is decreasing. In some embodiments, over at least 50% (or over at least 75%, at least 90%, at least 95%, or more (e.g., up to 100%)) of the distance through the shell region, in a direction from an exterior of the core region to an exterior of the shell region, and following a line segment that begins at the geometric center of the nanoparticle and extends outward to the exterior of the shell region, the constructive refractive index of the shell region is monotonically decreasing.

As noted above, certain embodiments are directed to composite materials. The composite materials can comprise a collection of nanoparticles (e.g., any of the nanoparticles described herein) embedded or otherwise contained within a matrix material. FIG. 2, for example, is a cross-sectional schematic illustration of composite material 200 according to certain embodiments. In FIG. 2, composite material 200 comprises a collection of nanoparticles 202. Composite material 200 also comprises matrix material 201, in which nanoparticles 202 are embedded.

In some embodiments, the composite material can be in the form of a layer. The term “layer” is generally used herein to refer to a form factor having a thickness dimension, a first lateral dimension that is perpendicular to the thickness dimension, and a second lateral dimension that is perpendicular to the thickness dimension and to the first lateral dimension, in which each of the first lateral dimension and the second lateral dimension has a length that is at least three (3) times the thickness dimension. A layer also has two “major surfaces,” which are the two surfaces that are defined by the two lateral dimensions. Referring to FIG. 2, for example, composite material 200 is in the form of a layer having a thickness 203, a first major surface 204, and a second major surface 205.

In some embodiments, the composite material is in the form of a layer having a thickness of at least 1 micrometer, at least 10 micrometers, at least 25 micrometers, at least 50 micrometers, at least 100 micrometers, at least 250 micrometers, at least 500 micrometers, or at least 750 micrometers. In some embodiments, the composite material is in the form of a layer having a thickness of less than or equal to 5 millimeters, less than or equal to 2 millimeters, less than or equal to 1 millimeter, less than or equal to 750 micrometers, less than or equal to 500 micrometers, or less. Combinations of these ranges are also possible (e.g., at least 1 micrometer and less than or equal to 5 millimeters). Other ranges are also possible.

The nanoparticles can be present in the composite material in any of a variety of suitable amounts. In some embodiments, at least 1 wt %, at least 2 wt %, at least 5 wt %, at least 10 wt %, at least 25 wt %, or at least 50 wt % (and/or, in some embodiments, less than or equal to 90 wt %, less than or equal to 80 wt %, less than or equal to 70 wt %, less than or equal to 60 wt %, less than or equal to 50 wt %, less than or equal to 40 wt %, less than or equal to 30 wt %, less than or equal to 20 wt %, or less) of the composite material is made of the nanoparticles (e.g., any of the nanoparticles described herein).

In some embodiments, the refractive index of the matrix material of the composite is smaller than the refractive index of the core regions of the nanoparticles. For example, in some embodiments, for at least one wavelength of visible electromagnetic radiation (e.g.. 633 nanometers or any other wavelength of visible electromagnetic radiation) at 25° C., the refractive index of the matrix material is less than or equal to 0.9 times (or less than or equal to 0.8 times, less than or equal to 0.7 times, less than or equal to 0.6 times, less than or equal to 0.5 times, or less than or equal to 0.4 times) the corresponding refractive index of the core regions of the nanoparticles. In some embodiments, for at least one wavelength of visible electromagnetic radiation (e.g., 633 nanometers or any other wavelength of visible electromagnetic radiation) at 25° C., the refractive index of the matrix material is less than or equal to 0.9 times (or less than or equal to 0.8 times, less than or equal to 0.7 times, less than or equal to 0.6 times, less than or equal to 0.5 times, or less than or equal to 0.4 times) the corresponding refractive index of the thermochromic material in the core regions of the nanoparticles.

In some embodiments, for at least 25% (or at least 50%, at least 75%, at least 90%, at least 95%, at least 99%, or up to 100%) of all wavelengths of visible electromagnetic radiation at 25° C., the refractive indices of the matrix material are less than or equal to 0.9 times (or less than or equal to 0.8 times, less than or equal to 0.7 times, less than or equal to 0.6 times, less than or equal to 0.5 times, or less than or equal to 0.4 times) the corresponding refractive indices of the core regions of the nanoparticles. In some embodiments, for at least 25% (or at least 50%, at least 75%, at least 90%, at least 95%, at least 99%, or up to 100%) of all wavelengths of visible electromagnetic radiation at 25° C., the refractive indices of the matrix material are less than or equal to 0.9 times (or less than or equal to 0.8 times, less than or equal to 0.7 times, less than or equal to 0.6 times, less than or equal to 0.5 times, or less than or equal to 0.4 times) the corresponding refractive indices of the thermochromic material in the core regions of the nanoparticles.

In some embodiments, the refractive index of the shell region of the nanoparticles in the composite is smaller than the refractive index of the matrix material of the composite. For example, in some embodiments, for at least one wavelength of visible electromagnetic radiation (e.g., 633 nanometers or any other wavelength of visible electromagnetic radiation) at 25° C., the refractive index of the shell region of the nanoparticles in the composite is less than or equal to 0.9 times (or less than or equal to 0.8 times, less than or equal to 0.7 times, less than or equal to 0.6 times, less than or equal to 0.5 times, or less than or equal to 0.4 times) the corresponding refractive index of the matrix material of the composite. In some embodiments, for at least one wavelength of visible electromagnetic radiation (e.g., 633 nanometers or any other wavelength of visible electromagnetic radiation) at 25° C., the refractive index of the shell region of the nanoparticles in the composite is less than or equal to 0.9 times (or less than or equal to 0.8 times, less than or equal to 0.7 times, less than or equal to 0.6 times, less than or equal to 0.5 times, or less than or equal to 0.4 times) the corresponding refractive index of the matrix material of the composite. In some embodiments, for at least 25% (or at least 50%, at least 75%, at least 90%, at least 95%, at least 99%, or up to 100%) of all wavelengths of visible electromagnetic radiation at 25° C., the refractive indices of the shell region of the nanoparticles in the composite are less than or equal to 0.9 times (or less than or equal to 0.8 times, less than or equal to 0.7 times, less than or equal to 0.6 times, less than or equal to 0.5 times, or less than or equal to 0.4 times) the corresponding refractive indices of the matrix material of the composite. In some embodiments, for at least 25% (or at least 50%, at least 75%, at least 90%, at least 95%, at least 99%, or up to 100%) of all wavelengths of visible electromagnetic radiation at 25° C., the refractive indices of the shell region of the nanoparticles in the composite are less than or equal to 0.9 times (or less than or equal to 0.8 times, less than or equal to 0.7 times, less than or equal to 0.6 times, less than or equal to 0.5 times, or less than or equal to 0.4 times) the corresponding refractive indices of the matrix material of the composite.

In certain embodiments, for at least one wavelength of visible electromagnetic radiation at 25° C. (e.g., 633 nanometers or any other wavelength of visible electromagnetic radiation) and/or for at least 25% (or at least 50%, at least 75%, at least 90%, at least 95%, at least 99%, or up to 100%) of all wavelengths of visible electromagnetic radiation at 25° C., the refractive index of the matrix material (nₘₐₜᵣᵢₓ), the refractive index of the shell region (nₛₕₑₗₗ), and the refractive index of the core region (n_{core}) are related as follows: n_{core}>nₘₐₜᵣᵢₓ>nₛₕₑₗₗ.

In some embodiments, the composite material can have a relatively high transmittance of visible electromagnetic radiation through the major surfaces of the composite material, even when it is loaded with a relatively high amount of nanoparticles comprising thermochromic material. For example, in some embodiments in which (1) the nanoparticles make up at least 10 wt % of the composite material (or at least 20 wt %, at least 30 wt %, and/or less than or equal to 50 wt %, less than or equal to 40 wt %, less than or equal to 30 wt %, or less than or equal to 20 wt % of the composite material) and (2) the refractive index of the matrix material with respect to at least one wavelength of visible electromagnetic radiation at 25° C. is less than or equal to 0.9 times the refractive index of the thermochromic material with respect to that wavelength of visible electromagnetic radiation at 25° C., the composite material has a transmittance of that wavelength of visible electromagnetic radiation (e.g., through the major surfaces of the composite material) of at least 50% (or at least 60%, at least 70%, and/or up to 80%, or up to 90%). In some such embodiments, the relationships of the previous sentence are true for at least 25%, at least 50%, at least 75%, at least 90%, at least 95%, or at least 99% (and/or, up to 100%) of all wavelengths of visible electromagnetic radiation. In some such embodiments, the transmittances above can be achieved at a temperature of 32° C. In some such embodiments, the transmittances above can be achieved even when the composite material is in the form of a layer having a thickness of at least 1 micrometer, at least 10 micrometers, at least 25 micrometers, at least 50 micrometers, at least 100 micrometers, at least 250 micrometers, at least 500 micrometers, or at least 750 micrometers (and/or less than or equal to 5 millimeters, less than or equal to 2 millimeters, less than or equal to 1 millimeter, less than or equal to 750 micrometers, less than or equal to 500 micrometers, or less).

In some embodiments, the integral visible solar transmittance (Tᵥᵢₛ) of the composite material at 32° C. can be at least 50% (or at least 60%, at least 70%, and/or up to 80%, or up to 90%). In some embodiments, the integral visible solar transmittance (Tᵥᵢₛ) of the composite material at 32° C. can be at least at least 50% (or at least 60%, at least 70%, and/or up to 80%, or up to 90%). In some embodiments, the integral visible solar transmittance (Tᵥᵢₛ) of the composite material at 85° C. can be at least 2, at least 5, or at least 10 (and/or up to 20) percentage points lower than the integral visible solar transmittance of the composite material at 32° C.

In some embodiments, the composite material has a relatively high Moderate Temperature Solar Modulation. As used herein, the “Moderate Temperature Solar Modulation” (ΔT_{sol,mod}) is calculated as follows:

$$Δ {T}_{sol , mod} = {T}_{sol , 32} - {T}_{sol , 85}$$

where T_{sol,32} is the integral solar transmittance at 32° C. and T_{sol,85} is the integral solar transmittance at 85° C. For a particular temperature, the integral solar transmittance (Tₛₒₗ) is calculated as follows:

$${T}_{sol} = {\int }_{300}^{2200} {φ}_{sol} ( λ ) T ( λ ) d λ / {\int }_{300}^{2200} {φ}_{sol} ( λ ) d λ$$

where T(λ) denotes the transmittance at wavelength λ and φₛₒₗ is the solar irradiance spectrum for an air mass of 1.5 (corresponding to the sun standing 37° above the horizon). In some embodiments, the composite material has a Moderate Temperature Solar Modulation of at least 5%, at least 10%, at least 15%, at least 20%, or at least 25%, or more. In some embodiments, the composite material has a Moderate Temperature Solar Modulation of less than or equal to 25%, less than or equal to 20%, less than or equal to 15%, less than or equal to 10%, or less.

In some embodiments, the composite material has a relatively low Moderate Temperature Visible Modulation. As used herein, the “Moderate Temperature Visible Modulation” (ΔT_{vis,mod}) is calculated as follows:

$$Δ {T}_{vis , mod} = {T}_{vis , 32} - {T}_{vis , 85}$$

where T_{vis,32} is the integral visible transmittance at 32° C. and T_{vis,85} is the integral visible transmittance at 85° C. For a particular temperature, the integral visible transmittance (Tᵥᵢₛ) is calculated as follows:

$${T}_{vis} = {\int }_{400}^{700} {φ}_{vis} ( λ ) T ( λ ) d λ / {\int }_{400}^{700} {φ}_{vis} ( λ ) d λ$$

where T(λ) denotes the transmittance at wavelength λ, and φᵥᵢₛ is the standard efficiency function for the photopic vision. In some embodiments, the composite material has a Moderate Temperature Visible Modulation of less than or equal to 25%, less than or equal to 20%, less than or equal to 15%, less than or equal to 10%, less than or equal to 5%, less than or equal to 2%, or less. In some embodiments, the composite material has a Moderate Temperature Visible Modulation of at least 0.1%, at least 1%, at least 2%, at least 5%, or more.

The composite materials can be used in any of a wide variety of applications. In some embodiments, the composite material forms a part of a window, a package, a screen, a lens, a mirror, a film, a panel, a display, a wafer, a coverslip, or a glaze. In some embodiments, the composite material forms all or part of a layer over the surface of a transparent material (e.g., a window, a package, a screen, a lens, a mirror, a film, a panel, a display, a wafer, a coverslip, or a glaze). In some embodiments, the composite material forms all or part of a layer between two or more transparent materials (e.g., between the panes of a dual pane window).

As noted above, certain aspects of the disclosure are related to methods.

In certain aspects, methods of making a nanoparticle are described. The nanoparticles that are made by these methods can correspond to any of the nanoparticles described above or elsewhere herein.

In some embodiments, the method comprises establishing a shell region (e.g., any of the shell regions described above or elsewhere herein) around a core region (e.g., any of the core regions described above or elsewhere herein). The shell region can be established around the core region, for example, by coupling a polymer (e.g., a gradient copolymer) to the core region.

In some embodiments, the method comprises forming the core region (e.g., by forming a collection of nanoparticles comprising thermochromic material, which can be used as core regions) and subsequently forming the shell over the core region that has been formed. In some embodiments, one or more additional materials can be added to the first part of the core region that has been formed (which may contain the thermochromic material), for example, by coating one or more additional materials over the originally-formed core region. As one example, a core region of thermochromic material (e.g., VO₂) can be formed, following by forming a coating of one or more materials (e.g., a polymer material (e.g., poly(vinylpyrrolidone) (PVP); an oxide material (e.g., SiO₂); and/or other materials) over the thermochromic material. In some such embodiments, the material of the shell region (e.g., a gradient copolymer) can then be attached to the core region, optionally with one or more linker moieties.

In some embodiments, the method comprises coupling a gradient copolymer to a core region comprising a thermochromic material, such that the gradient copolymer forms at least a portion of a shell region around the core region. In some embodiments, the gradient copolymer may be coupled to the core region using a linker moiety (e.g., silitrane or PMOS).

In certain aspects, methods of making a composite article are described. The methods of making a composite article can be used to make any of the composite articles described above or elsewhere herein.

In some embodiments, the method comprises dispersing nanoparticles within a liquid matrix material and solidifying the liquid matrix material such that the nanoparticles are dispersed within the solidified matrix material. The matrix material can be solidified using any of a variety of suitable processes. For example, in some cases, a chemical reaction can be used to solidify the matrix material (e.g., in cases where thermoset polymer is used as the matrix material). In certain embodiments, the matrix material can be solidified by lowering its temperature below its melting point (e.g., in cases where thermoplastic polymer is used in the matrix material). Other solidification methods are also possible.

The core regions of the nanoparticles described herein can comprise any of a variety of suitable materials in any of a variety of configurations.

As noted above, a variety of thermochromic materials can be used in the various embodiments described herein. In some embodiments, the thermochromic material may comprise or be formed of at least one inorganic material. In some embodiments, the thermochromic material comprises a metal oxide (e.g., vanadium oxide (VO₂), zinc oxide (ZnO), titanium dioxide (TiO₂), and/or lead oxide (PbO)). In some embodiments, the thermochromic material comprises VO₂. In some embodiments, the thermochromic material comprises at least one metal oxide. In some embodiments, the thermochromic material comprises two or more different metal oxides.

In certain embodiments, the thermochromic material can have a relatively high degree of thermochromism with respect to near infrared electromagnetic radiation. For example, in certain embodiments, for at least one wavelength (or for at least 10%, at least 25%, at least 50%, at least 75% of wavelengths, and/or up to 80%, up to 90%, up to 95%, up to 99%, or up to 100% of wavelengths) of electromagnetic radiation between 700 nm and 2500 nm, when the thermochromic material is heated from 32° C. to 85° C., the transmittance of that wavelength(s) decreases by at least 5%, at least 10%, or at least 20% (and/or, up to 30%, up to 50%, or more). In this context, a decrease in transmittance refers to an absolute decrease in transmittance, such that a decrease from 50% transmittance to 10% transmittance would correspond to decreasing the transmittance by 40% (and, similarly, a decrease in transmittance from 50% transmittance to 30% transmittance would correspond to decreasing the transmittance by 20%). In some embodiments, for at least one wavelength (or for at least 10%, at least 25%, at least 50%, at least 75% of wavelengths, and/or up to 80%, up to 90%, up to 95%, up to 99%, or up to 100% of wavelengths) of electromagnetic radiation between 700 nm and 1000 nm, when the thermochromic material is heated from 32° C. to 85° C., the transmittance of that wavelength(s) decreases by at least 5%, at least 10%, or at least 20% (and/or, up to 30%, up to 50%, or more).

In certain embodiments, the nanoparticles comprising the core region and the shell region can have a relatively high degree of thermochromism with respect to near infrared electromagnetic radiation. For example, in certain embodiments, for at least one wavelength (or for at least 10%, at least 25%, at least 50%, at least 75% of wavelengths, and/or up to 80%, up to 90%, up to 95%, up to 99%, or up to 100% of wavelengths) of electromagnetic radiation between 700 nm and 2500 nm, when the nanoparticles comprising the core region and the shell region are heated from 32° C. to 85° C., the transmittance of that wavelength(s) decreases by at least 5%, at least 10%, or at least 20% (and/or, up to 30%, up to 50%, or more). In some embodiments, for at least one wavelength (or for at least 10%, at least 25%, at least 50%, at least 75% of wavelengths, and/or up to 80%, up to 90%, up to 95%, up to 99%, or up to 100% of wavelengths) of electromagnetic radiation between 700 nm and 1000 nm, when the nanoparticles comprising the core region and the shell region are heated from 32° C. to 85° C., the transmittance of that wavelength(s) decreases by at least 5%, at least 10%, or at least 20% (and/or, up to 30%, up to 50%, or more). In these contexts, a decrease in transmittance refers to an absolute decrease in transmittance, such that a decrease from 50% transmittance to 10% transmittance would correspond to decreasing the transmittance by 40% (and, similarly, a decrease in transmittance from 50% transmittance to 30% transmittance would correspond to decreasing the transmittance by 20%).

In some embodiments, the transmittance of the nanoparticle comprising the core and the shell is greater, over at least a portion of the visible spectrum, than the transmittance of the core alone. For example, in certain embodiments, for at least one wavelength (or for at least 10%, at least 25%, at least 50%, at least 75% of wavelengths, and/or up to 80%, up to 90%, up to 95%, up to 99%, or up to 100% of wavelengths) of visible electromagnetic radiation, the transmittance of the nanoparticles comprising the core region and the shell region is at least at least 5%, at least 10%, at least 20%, at least 25%, at least 30%, at least 35%, at least 40%, at least 45%, or at least 50% (and/or, up to 50%, up to 60%, up to 70%, up to 80%, or more) greater than the transmittance of the cores alone. In this context, the differences in transmittance are absolute differences, such that a transmittance of 50% would be 40% greater than a transmittance of 10% (and, similarly, a transmittance of 50% would be 20% greater than a transmittance of 30%).

In some embodiments, the transmittance of the composite material comprising nanoparticles comprising cores and shells is greater, over at least a portion of the visible spectrum, than the transmittance of the composite comprising nanoparticles comprising the core alone. For example, in certain embodiments, for at least one wavelength (or for at least 10%, at least 25%, at least 50%, at least 75% of wavelengths, and/or up to 80%, up to 90%, up to 95%, up to 99%, or up to 100% of wavelengths) of visible electromagnetic radiation, the transmittance of the composite material comprising nanoparticles comprising the core region and the shell region is at least 5%, at least 10%, at least 20%, at least 25%, at least 30%, at least 35%, at least 40%, at least 45%, or at least 50% (and/or, up to 50%, up to 60%, up to 70%, up to 80%, or more) greater than the transmittance of an equivalent composite material comprising nanoparticles comprising the cores alone. In this context, the differences in transmittance are absolute differences, such that a transmittance of 50% would be 40% greater than a transmittance of 10% (and, similarly, a transmittance of 50% would be 20% greater than a transmittance of 30%).

In some embodiments, the thermochromic material is part of a core region comprising at least one metal oxide (e.g., VO₂, ZnO, TiO₂, PbO) that is at least partially surrounded by a shell region comprising at least one other material. In some embodiments, the thermochromic material is part of a core region comprising at least one metal oxide (e.g., VO₂, ZnO, TiO₂, PbO) that is at least partially surrounded by a shell region comprising at least one metal oxide and/or metalloid oxide (e.g., Al₂O₃, ZnO₂, SiO₂, Cr₂O₃). In some embodiments, the thermochromic material is part of a core region comprising VO₂ that is at least partially surrounded by silica (SiO₂).

In some embodiments, the core region of the nanoparticle comprises at least one thermochromic material and at least one additive (e.g., a molecule or dopant such as an ionic dopant) suitable for enhancing the thermal, electrical, optical, or structural properties of the thermochromic material. In some embodiments, the core region of the nanoparticle comprises thermochromic material, at least one metal oxide and/or metalloid oxide, and at least one additive suitable for enhancing the thermal, electrical, optical, or structural properties of the thermochromic material. Examples of additives suitable for enhancing the thermal, electrical, optical, or structural properties of thermochromic materials include, but are not limited to, Mo⁺⁶, W⁺⁶, Nb⁺⁵, Ta⁺⁵, Sb^{+S}, F⁻, Al⁺³, W⁺⁶, or W⁺⁴).

In some embodiments, the thermochromic material comprises at least one dopant. In some embodiments, the dopant is a metal ion (e.g., Al or W ion). In some embodiments, the dopant is a non-metal ion (e.g., F ion). In certain embodiments, the use of a metal dopant (e.g., Mo⁺⁶, W⁺⁶, Nb⁺⁵, Ta⁺⁵, Sb⁺⁵, Al⁺³, W⁺⁶, or W⁺⁴) can reduce the transition temperature. In some embodiments, the use of a non-metal dopant (e.g., F) can improve transparency.

The shell regions of the nanoparticles described herein can comprise any of a variety of suitable materials in any of a variety of configurations.

In some embodiments, the shell region comprises polymeric material (e.g., a gradient copolymer and/or a block copolymer). In some embodiments, the copolymer comprises at least a first monomer moiety comprising PMMA and at least a second monomer moiety comprising P13FOMA. In some embodiments, the gradient copolymer comprises PMMA-grad-P13FOMA. In some embodiments, the block copolymer comprises PMMA-block-P13FOMA. In some embodiments, the copolymer further comprises the PMOS. In some embodiments, the copolymer may be fluorinated. In some embodiments, the copolymer may be chlorinated. In some embodiments, the copolymer is further modified. Additional examples of materials that may be part of the copolymer include, but are not limited to, styrene (St), acrylic acid (AA), tert-butyl acrylate (tBA), octadecyl methacrylate (ODMA), methyl methacrylate (MMA), polymethyl methacrylate (PMMA), high MW PMMA, n-butyl acrylate (nBA), n-butyl methacrylate (nBMA), octyl methacrylate (OMA), poly(1H,1H,2H,2H-perfluorooctyl methacrylate) (P13FOM A), poly methacryloxypropyl silatrane (PMOS), and methacryloxypropyl silatrane (MOS).

In some embodiments, the polymer within the shell region comprises at least one organic polymer (i.e., a polymer having carbon in its backbone). In some embodiments, it can be particularly advantageous to employ a polymer in the shell region (e.g., a gradient copolymer in the shell region) in which at least 60 at %, at least 75 at %, at least 90 at %, or at least 95 at % of the backbone atoms are carbon, nitrogen, oxygen, phosphorous, or sulfur. In some embodiments, it can be particularly advantageous to employ a polymer in the shell region (e.g., a gradient copolymer in the shell region) in which at least 60 at %, at least 75 at %, at least 90 at %, or at least 95 at % of the backbone atoms are carbon. In some embodiments, the polymer comprises at least one monomer moiety wherein at least 60 at % (or at least 75 at %, at least 90 at %, or at least 95 at %) of the atoms of the monomer moiety are carbon, nitrogen, oxygen, phosphorous, or sulfur. In some embodiments, the polymer comprises at least one monomer moiety wherein at least 60 at % (or at least 75 at %, at least 90 at %, or at least 95 at %) of the atoms of the monomer moiety are carbon.

Any of a variety of materials can be used as the matrix material of the composites described herein. In some embodiments, the matrix material comprises metal, ceramic, polymer, or carbon/graphite. In some embodiments, the matrix material is a polymer. In some embodiments, the matrix material is a thermoset (e.g., epoxies, phenolics) or thermoplastic (e.g., polycarbonate, polyvinylchloride, nylon, acrylics). In some embodiments, the matrix material comprises PMMA. In some embodiments, it is advantageous to use matrix materials that can be transformed from a liquid to a solid under benign conditions. Examples of such materials include, but are not limited to, polymers (e.g., thermoset polymers, thermoplastic polymers, and the like), hydrogels, organogels, metal organic frameworks (MOFs), covalent organic frameworks (COFs), and porous coordination polymers (PCP).

In some embodiments, it may be particularly advantageous for the matrix material to comprise at least one of the materials that make up the polymer within the shell region of the nanoparticle. For example, the matrix material and the polymer within the shell region of the nanoparticle may both comprise the same monomer material. As one particular example, if the shell region comprises the copolymer PMMA-grad-P13FOMA, then it may be particularly advantageous, in some embodiments, for the matrix material to also comprise PMMA.

U.S. Provisional Patent Application No. 63/395,989, filed Aug. 8, 2022, and entitled “Nanoparticle-Containing Media Exhibiting Enhanced Optical Transparency, Related Nanoparticles, and Associated Systems and Methods,” is incorporated herein by reference in its entirety for all purposes.

The following example is intended to illustrate certain embodiments of the present invention, but does not exemplify the full scope of the invention.

### EXAMPLE

Growing populations and technological advancements have accelerated the worldwide demand for the construction of buildings both in the form of private houses and commercial structures. This has inordinately increased energy consumption and accounts for 20% to 40% of measured energy use. In the United States, per estimations provided by the Department of Energy (DOE), a significant amount (about 41%) of total energy consumption is utilized by buildings' heating and air conditioning (HVAC) systems. This promotes carbon dioxide (CO₂) emissions and plays a major role in global warming.

Building fenestrations, which are the root cause of energy exchange from building to the environment and vice-versa, could be improved. Current technologies are primarily directed to the use of photochromic and electrochromic substances to mitigate solar heat gain problems, but their applications are limited due to the high cost of production, and they frequently affect the transmittance of visible light, which necessitates the use of artificial lightning. Notably, these photo- and electrochromic materials are limited because of their temperature-invariant nature and are incapable of offsetting heat-gain problems during the winter.

Thermochromic materials that can be used as a glazing material in building fenestrations may offer a solution. Various thermochromic metal oxides (e.g., zinc oxide (ZnO), titanium dioxide (TiO₂), lead oxide (PbO)), vanadium oxide [VO₂ (M-phase)]) are promising candidates for use in “smart windows” applications. A reversible phase change of VO₂ from the monoclinic semiconducting phase to the rutile metallic phase occurs as a function of temperature, making it capable of modulating solar radiations in the near infrared (NIR) range. However, widespread applications of VO₂-based coatings have been strongly hindered by their high visible light scattering, high metal-to-insulator transition (MIT) temperature (68° C.), and limited commercial production rates.

Using effective medium theory (EMT), the trade-off between the Tᵥᵢₛ and ΔTₛₒₗ can be overcome by infiltrating the VO₂ NPs into a dielectric matrix with glass-like properties, such as polymer, also resulting in enhanced stability of the embedded VO₂ NPs.

This example describes articles, systems, and methods that can be used to address the large refractive index [n(λ)]mismatch between VO₂ and matrix materials. One way to address the mismatch is by grafting copolymers with a low n(k) fluorinated polymer to cloak VO₂ NPs. Fluorinated copolymers have been synthesized with different sequential arrangements of PMMA, such as gradient copolymer (GCP) and block copolymer (BCP). During the formulation of the copolymer, a small block of poly(methacryloxypropyl silatrane) (PMOS), was introduced to act as an anchoring moiety to VO₂ NPs to obtain a composition of PMMA-co-P13FOMA-co-PMOS. The gradient copolymer of PMMA (n(λ) 1.49) and poly(1H,1H,2H,2H-perfluorooctyl methacrylate) (P13FOMA) [n(λ) 1.33-1.44](PMMA-grad-P13FOMA) was synthesized via concurrent tandem catalysis (CTC) that comprises metal alkoxide-mediated transesterification of methyl methacrylate (MMA) with 1H,1H,2H,2H-perfluorooctanol (13FOOH) and ruthenium-catalyzed living radical polymerization (LRP) of the respective monomers followed by block of PMOS (PMMA-grad-P13FOMA-block-PMOS) via a sequential tandem catalysis reaction. A triblock copolymer (PMMA-block-P13FOMA-block-PMOS) was synthesized using Reversible Addition-Fragmentation chain Transfer (RAFT) polymerization. Thermochromic nanocomposite films were fabricated with excellent transparency by embedding low RI VO₂@SiO₂@GCP or BCP composite NPs in a continuous high MW PMMA film [n(λ) 1.49].

Synthesis of the pure M-phase VO₂ NPs via conventional batch hydrothermal methods is cumbersome due to the coexistence of different VO₂ polymorphs (B-, A-, M-, D-, and P-phases) and the accompaniment of various oxidation states (V²⁺, V³⁺, V⁴⁺, and V⁵⁺) This method also generally requires additional post-annealing steps to obtain pure M-phase VO₂ NPs from the intermediates of VO₂(A) and VO₂(B) polymorphs, leading to high production costs. In this example, a custom-built continuous flow hydrothermal (CFHT) reactor was used to quickly prepare pure and uniform-shaped VO₂ NPs. Moreover, the use of high temperature and high pressure further elevated production rates. To obtain core-shell particles with organic-inorganic segments, the synthetic GCP or BCP were chemically tethered to silica-modified VO₂ NPs (VO₂@SiO₂) using silatrane as an anchoring moiety. This approach facilitated the homogeneous distribution of VO₂ NPs in the polymer matrix, providing environmental stability. PMMA/VO₂@SiO₂@GCP or BCP composite solutions were coated over various substances, such as silicon wafers and quartz coverslips, to study RI and optical properties, respectively. The tailor-made, low RI fluorinated copolymer was used to match the high RI of VO₂ NPs with the RI of the dispersion matrix to obtain an optically transparent thermochromic film.

### Results and Discussion

Optical transparency is an important property for some materials, especially when they are used in specific applications, such as packaging, displays, and glazing. Fresnel reflection from the interface of two media with different refractive indices can generate surface glare, resulting to an opaque film. Thus an anti-reflection coating (ARC) plays a major role in imparting transparency to the system by reducing Fresnel reflection. Described herein is the synthesis of low RI copolymers with different polymer sequences (GCP or BCP) that can effectively cloak VO₂ NPs having a very high RI of >2. These polymers were used to prepare core-shell VO₂@SiO₂@GCP or VO₂@SiO₂@BCP NPs, which were further incorporated into a continuous PMMA matrix of MW 1,20,000 g/mol to fabricate transparent thermochroic nanocomposite films. Corroboration of the effect of copolymer sequences in GCP or BCP over the modulation in RI of VO₂ NPs embedded nanocomposite film is provided in the discussion below.

Preparation of VO₂ NPs as a starting point for the transparent nanocomposite film formation. The limited commercial availability of the M-phase VO₂ nanoparticles and their high expense, motivated the design of the custom-built continuous flow hydrothermal (CFHT) reactor and use of the CFHT to synthesize VO₂ NPs having a particle diameter below 100 nm.

It has been reported that particles' scattering intensity is proportional to rₚ³(r, radius of the particle), which means formation of a film with large particle diameters leads to poor visible light transparency. Hydrothermal synthesis of VO₂ NPs using supercritical (SC) water was used to prepare nano-sized particles having a diameter below 100 nm, and to avoid Mie scattering.

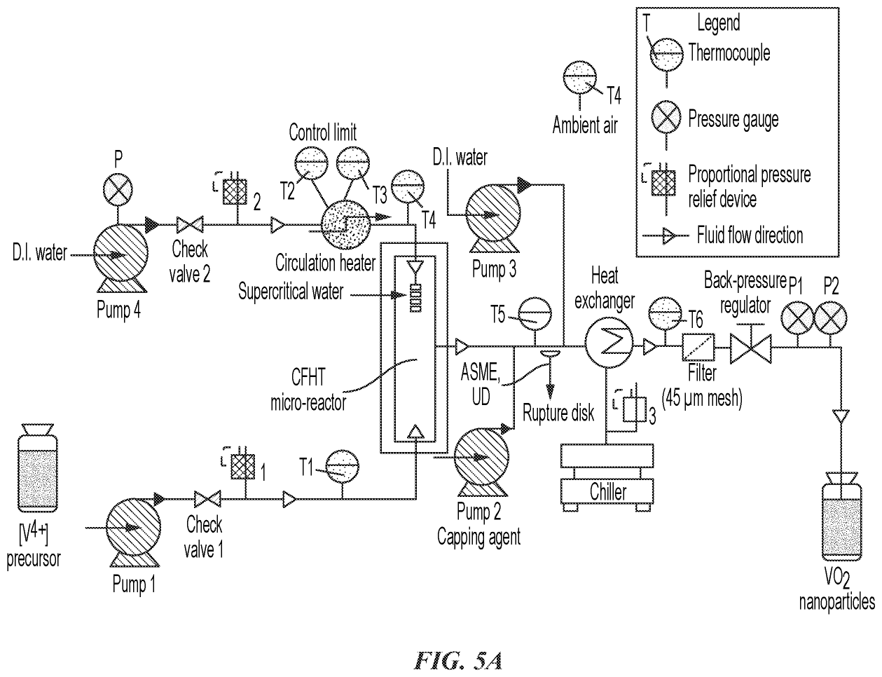

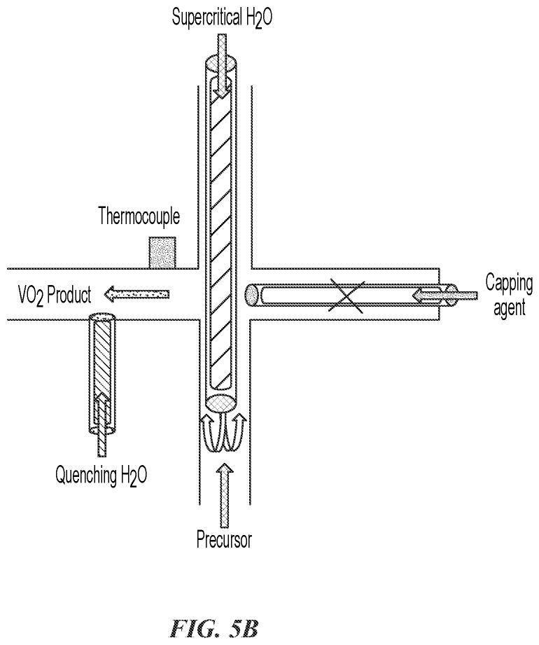

FIG. 5A is a schematic representation of a continuous flow hydrothermal (CFHT) apparatus that was used to generate VO₂ nanoparticles. The advantages of using the CFHT technique are—i) a supersaturated solution of the NPs can be achieved easily due to the insolubility of the NPs in the supercritical water, ii) increasing the amount of H₃O⁺ and —OH groups facilitates the hydrolysis process, and iii) the precursor decomposition rate can be easily tuned by modulating the temperature, which controls the nucleation and growth rate of the NPs. This facilitates the preparation of NPs with diameter of <100 nm. A temperature of 450° C. and a precursor flow rate of 30 mL min⁻¹ were found to be particularly advantageous to synthesize spherical VO₂ particles of 75±10 nm in diameter. The mechanism behind the VO₂ NPs synthesis process at the reaction zone is shown in FIG. 5B.

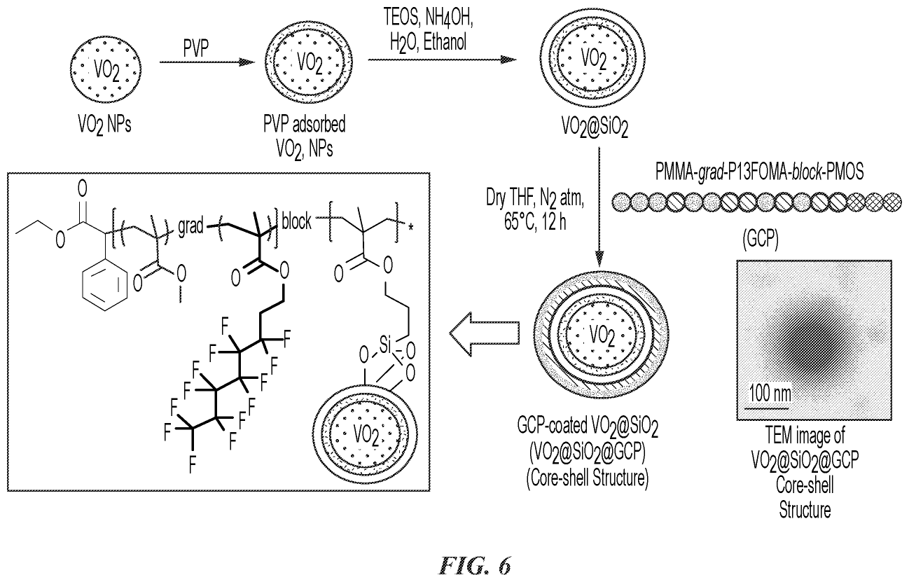

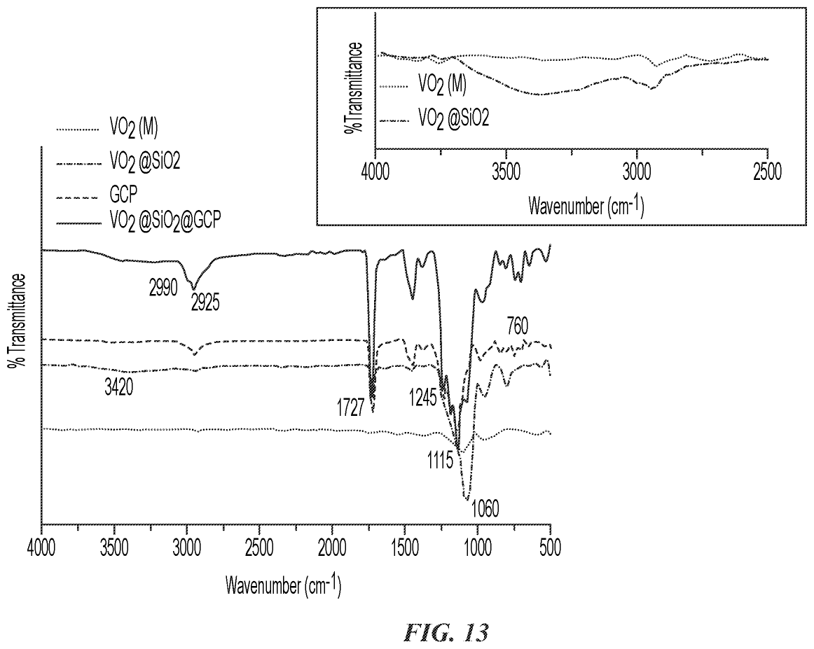

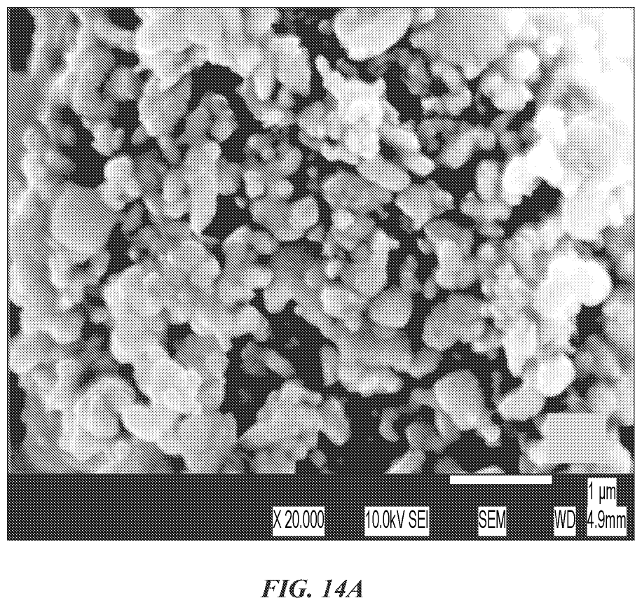

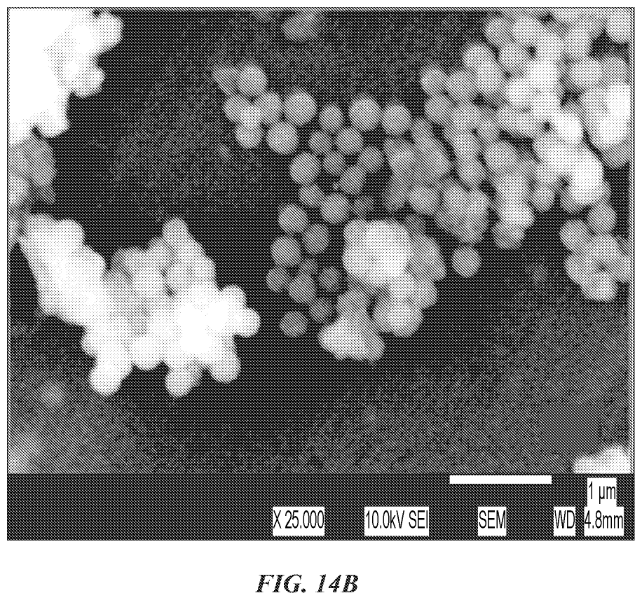

To introduce hydroxyl groups (—OH) for anchoring with the silatrane containing copolymer, VO₂ NPs were modified with silica (VO₂@SiO₂) via a modified Stöber process. In this process, the VO₂ surface was initially treated with low MW PVP in aqueous ethanol solution to prevent the agglomeration and facilitate the anchoring of the silane moiety to the NPs surface as shown in FIG. 6. Introduction of the silane increased the free hydroxyl groups (—OH) at the surface of the VO₂ NPs, offering an arena for the GCP to be anchored using its silatrane unit as shown in FIG. 6. Appearance of the broad vibration peak in FTIR at 3420 cm¹ upon modification of VO₂ NPs with silica indicates the presence of surface —OH groups (FIG. 13).

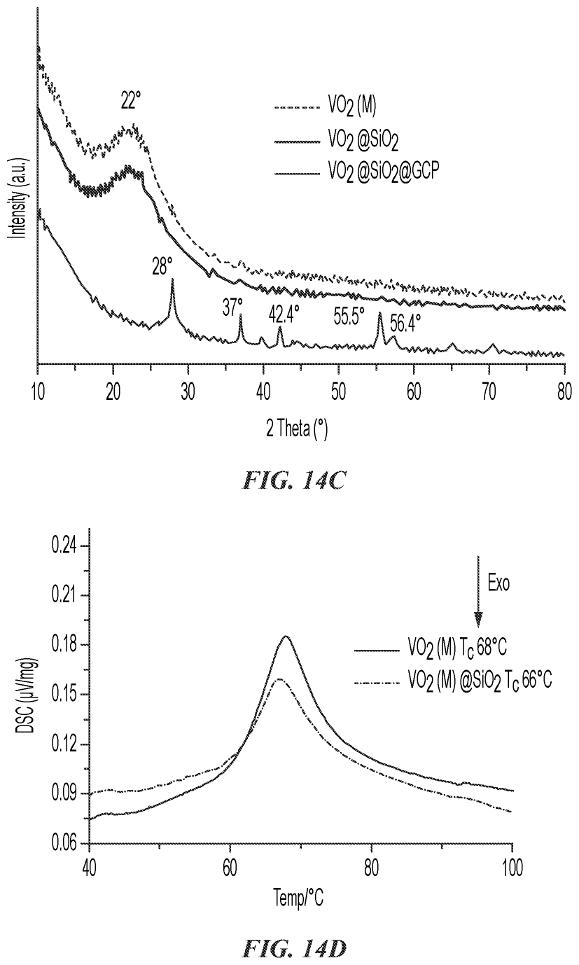

Surface morphology of the synthesized VO₂ NPs and the silica modified NPs was observed using FESEM. Hydrothermally synthesized VO₂NPs showed a spherical morphology having an average diameter in the range of (75±10) nm which was increased to 120 ±10 nm after modification with SiO₂, as observed in FIG. 14A and FIG. 14B.

The effect of this modification was also reflected in the X-ray diffraction pattern. For the pristine VO₂ NPs, peaks appeared at 2θ=28.0, 37.0°, 42.4°, 55.5°, and 56.4° corresponding to the (011), (200), (212), (220), and (022) planes in monoclinic VO₂. Upon silica modification, a broad peak was observed at 22°, which is a characteristic X-ray diffraction peak of SiO₂ (FIG. 14C). Interestingly, the addition of a SiO₂ layer did not significantly alter the transition temperature of VO₂ NPs, which was determined using DSC analysis (FIG. 14D). A minor reduction in the transition temperature of VO₂@SiO₂ (T_{c} 66° C.) compared to the pristine VO₂(M) (68° C.) was evidenced from the DSC thermogram.

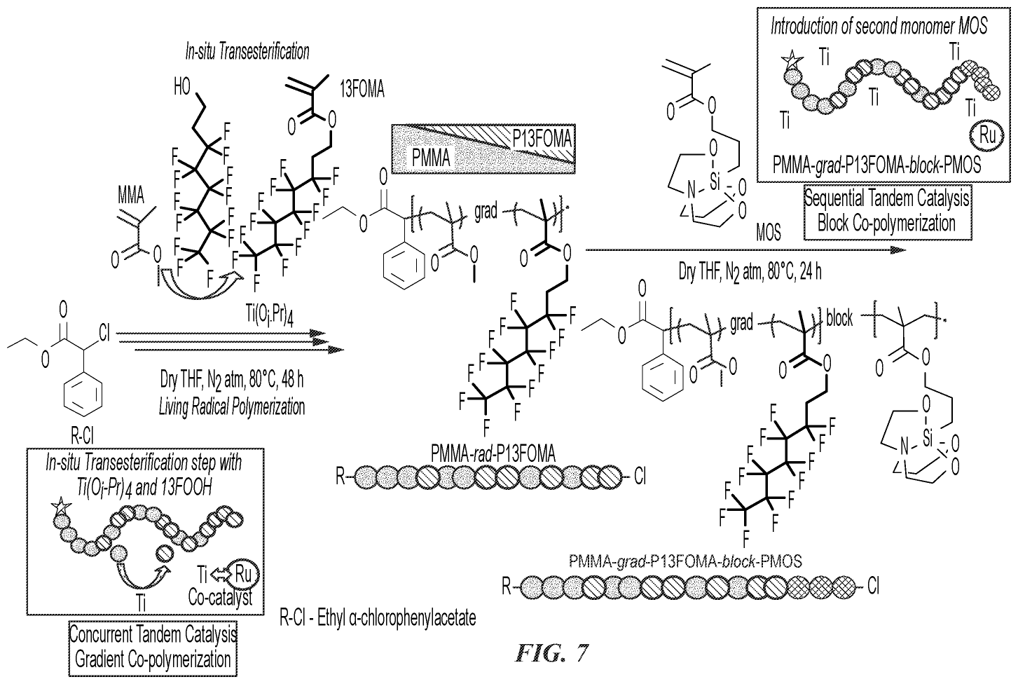

After the VO₂NPs synthesis, the low RI copolymers were prepared. Gradient copolymer with different PMMA to P13FOMA compositions (PMMA-grad-P13FOMA) were prepared using concurrent tandem catalysis living radical polymerization (LRP) of MMA and subsequent transesterification of the formed polymer with 13FOOH. In the successive step, block copolymerization of MOS was carried out using sequential tandem catalysis reaction to get PMMA-grad-P13FOMA-block-PMOS copolymer, as shown in FIG. 7.

The gradient copolymer (GCP) was prepared so that a gradient of RI could be achieved where PMMA (RI 1.49) formed the outer part and the fluorinated polymer (P13FOMA, RI 1.33-1.44) gradually and seamlessly increased from the initiating terminal end to the growing terminal end (FIG. 6), when the GCP was anchored over the VO₂@SiO₂ NPs surface. Here, the PMOS moiety of the copolymer acted as an anchoring unit to the NPs. Silatrane was selected over silane due to its stability in wet conditions and fast reaction ability.

The tandem catalysis approach described herein was used because it is a very convenient one-pot methodology. Different reactions can be performed either concurrently or sequentially, assisted by suitable combinations of catalysts to obtain the final product more directly and efficiently, compared to a multi-step synthesis process, which generally requires stringent isolation and purification steps. However, the high compatibility between the active species and intermediates of various catalytic cycles is an important factor for this reaction. As a result, catalyst selection is an important step when conducting these types of reactions.

Incorporation of the fluorous polymer in the GCP was carried out using a transesterification reaction, which is a very simple and versatile way to produce an ester compound (R₁COOR₃) by the help of other ester compounds (R₁COOR₂) and alcohols (R₃OH). The mechanism behind the tandem catalysis reactions (concurrent and sequential) and transesterification are shown in the inset of FIG. 7.

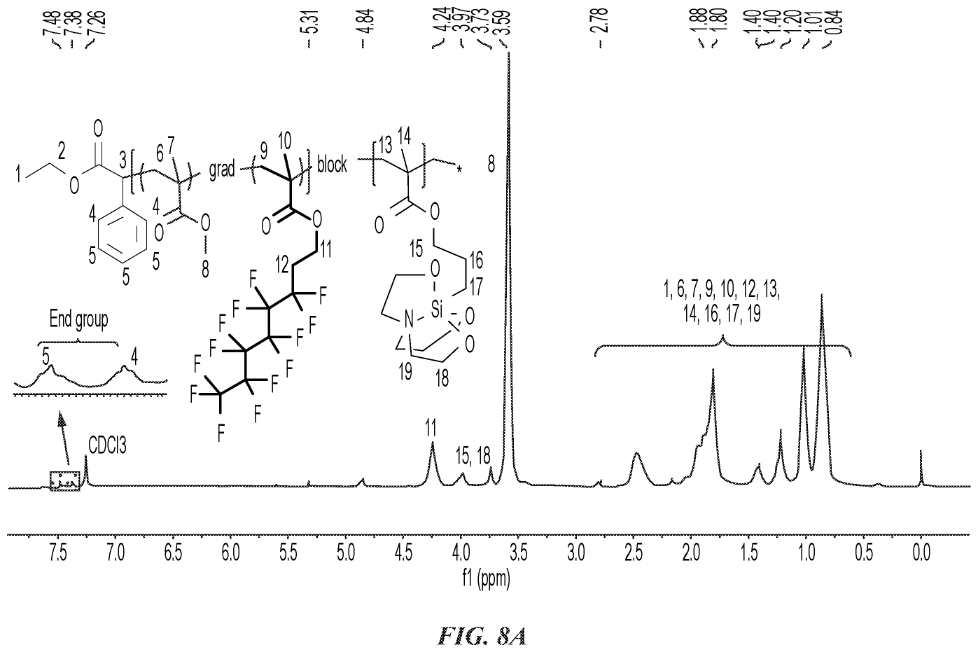

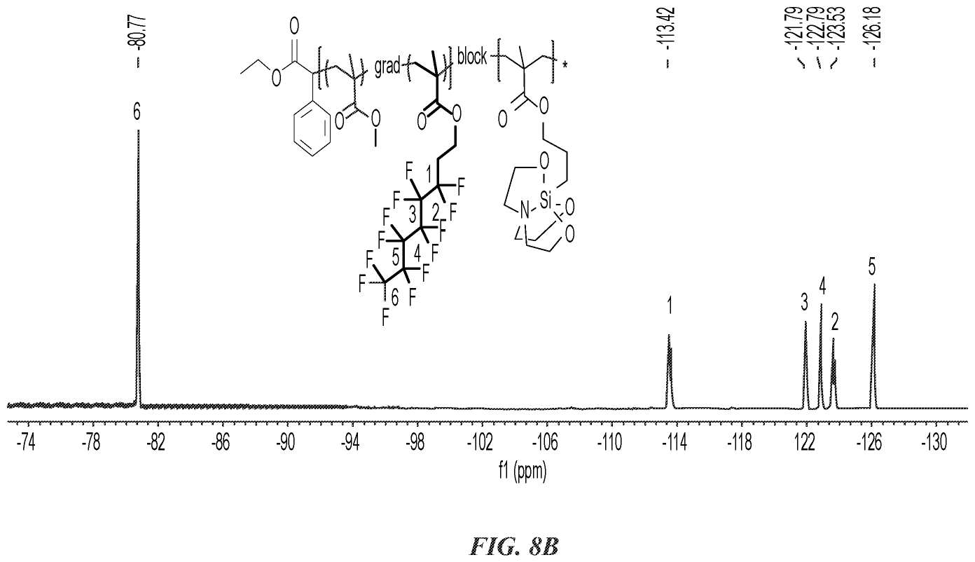

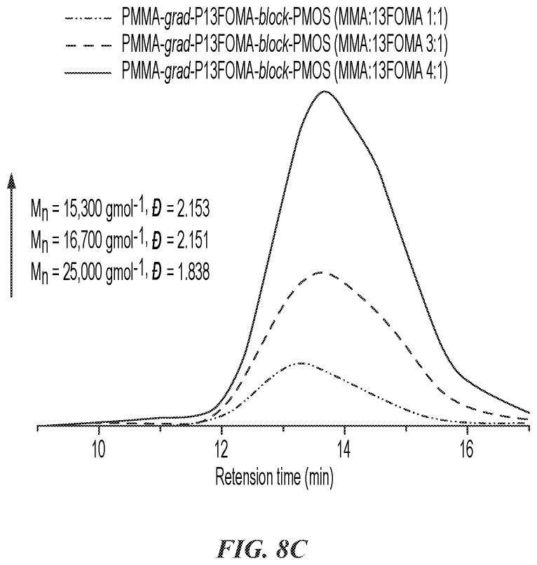

The as-prepared GCP was characterized with ¹H and ¹⁹F NMR studies, as well as SEC and FTIR analyses. In ¹H NMR, existence of the resonance peak at δ=7.26-7.48 ppm (aromatic protons, H4 and H5) (FIG. 8A) indicated presence of the end group coming from the initiator ethyl-α-chloro phenyl acetate (ECPA). The characteristic resonance peak for the PMMA segment was found at δ=3.59 ppm (—O—CH₃, H8). Similarly, occurrence of the P13FOMA segment was identified by the resonance peak at δ=4.24 ppm (—O—CH₂—, H11).

Presence of the silatrane moiety in the copolymer composition was confirmed by the resonance peaks at δ=3.73 ppm (—CH₂—CH₂—O—, H18) and 3.97 ppm (—O—CH₂—, H15). For more precise determination of the existence of the fluorous polymer segment in the GCP, ¹⁹F NMR was performed (FIG. 8B). The characteristic peaks were obtained at δ=−113.42 ppm (—CH₂—CF₂—) and −80.77 ppm (—CF₃).

Average molecular weights of the synthesized copolymers with different molar compositions of MMA:13FOOH such as 1:1, 3:1 and 4:1 were determined using SEC (FIG. 8C). Polystyrene was used as a calibration standard. From the SEC traces, it was observed that with increased 13FOOH relative molar ratio (1:1), the percentage conversion was high, leading to high MW copolymer (Mn 25,000 g mol⁻¹, Ð 1.838). Lower conversion of the monomer occurred when the relative molar ratio of 13FOOH was kept low (4:1) (Mn 15,300 g mol⁻¹, Ð 2.153). This narrow polydispersity (Ð) is reflective of the controlled approach of the tandem catalysis reaction.

It was found that a copolymer with MMA:13FOOH molar ratio of 4:1 offered superior transparency when compared to the rest of the compositions. Therefore, the composition of 4:1 was selected for further analysis. The prepared GCP was further characterized by FTIR analysis. Presence of the vibrational peaks at 1727 cm⁻¹, 1245 cm⁻¹, 1115 cm⁻¹, 1060 cm⁻¹, and 760 cm⁻¹ were attributed to the presence of >C═O, CF₃, CF₂, Si—O and Si—C stretching frequencies respectively (FIG. 13) which indicated the presence of PMMA, P13FOMA, and PMOS in the copolymer.

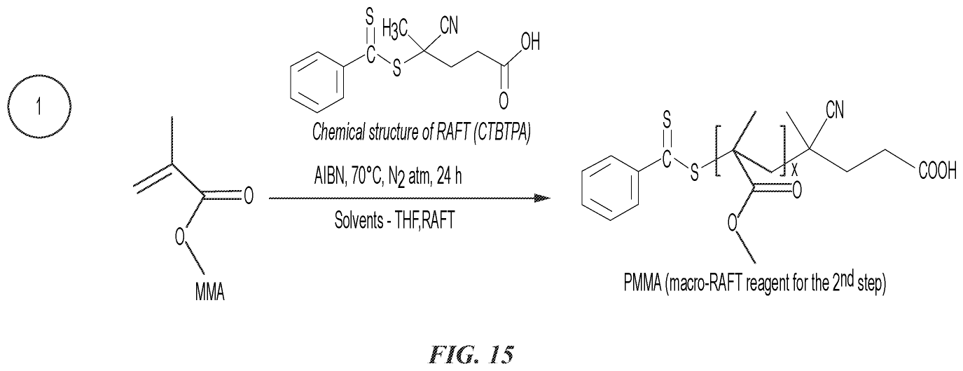

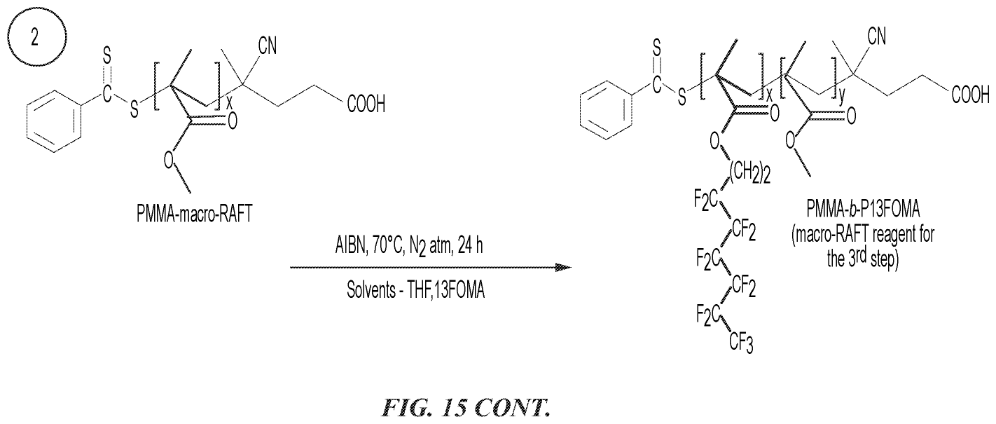

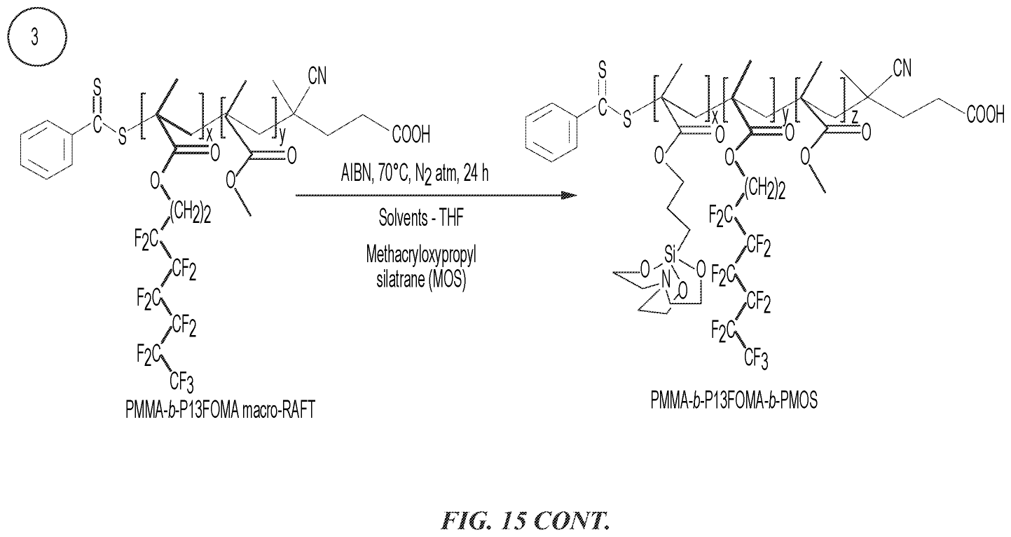

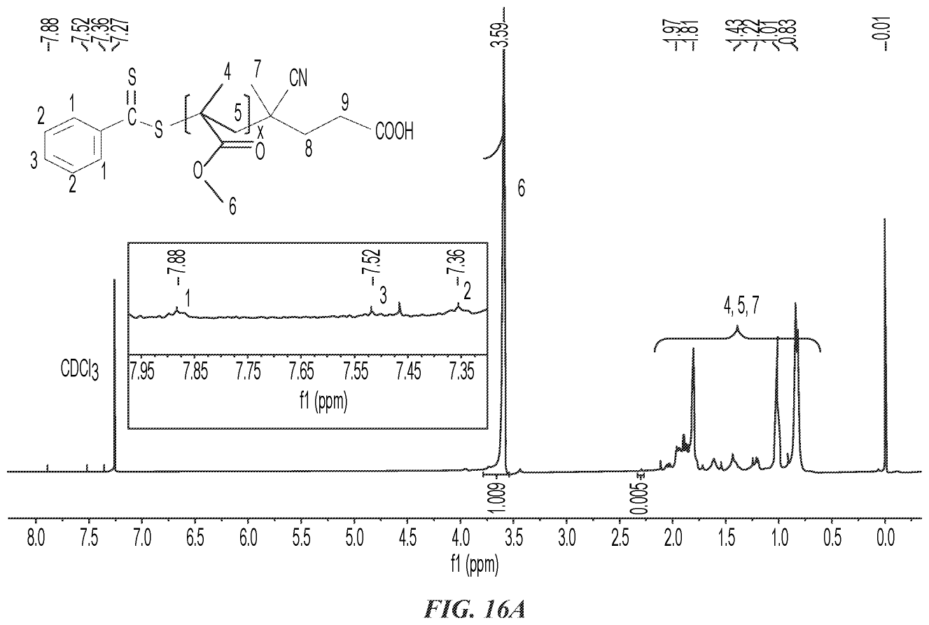

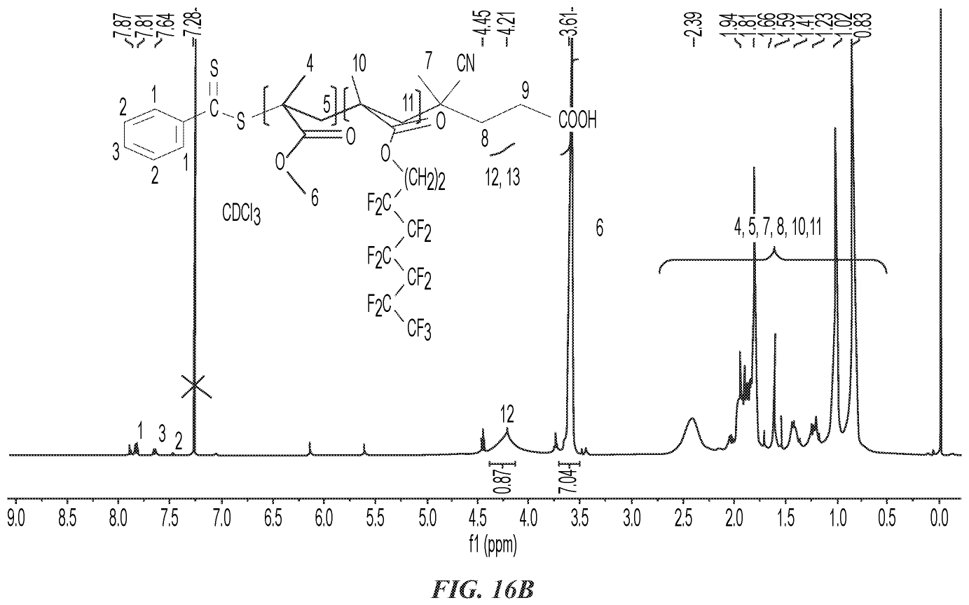

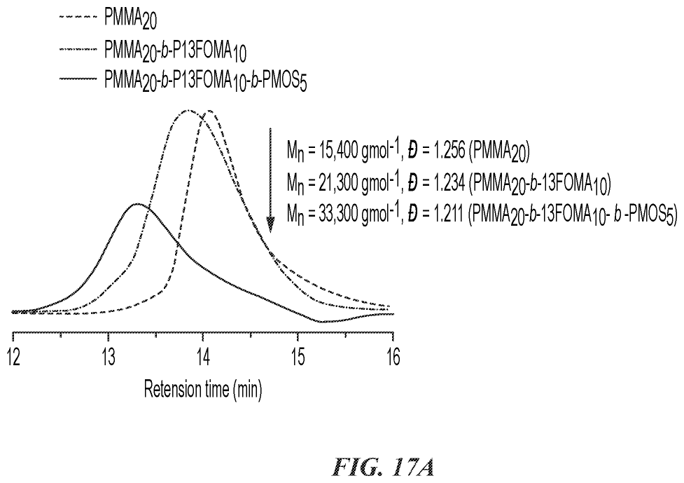

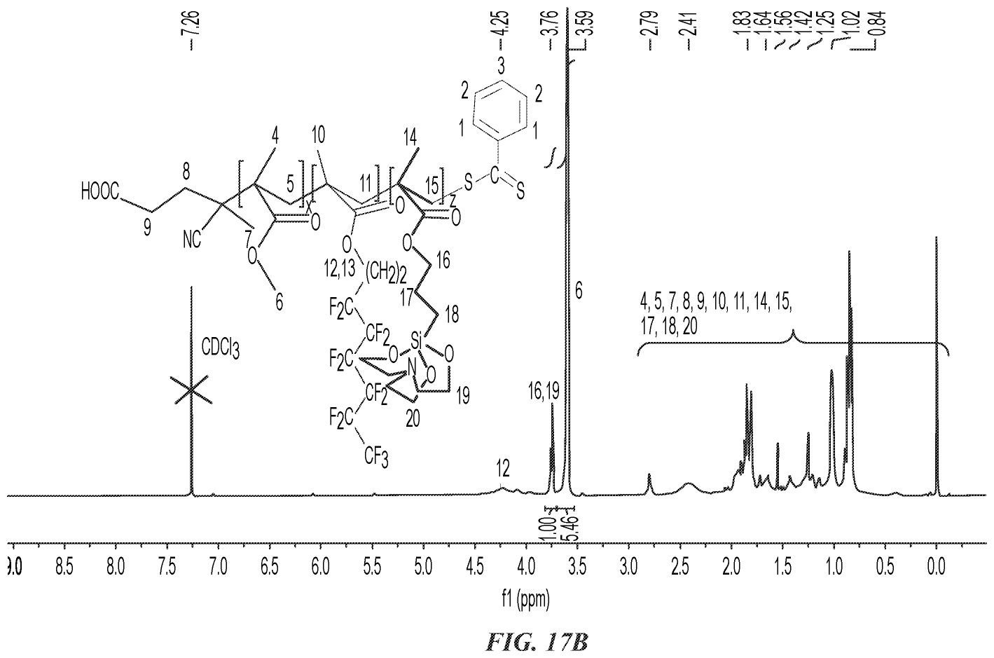

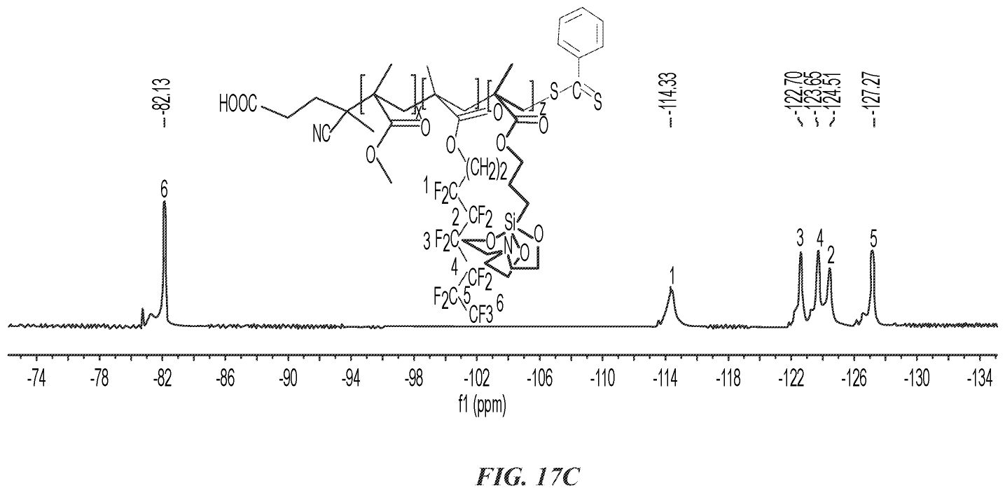

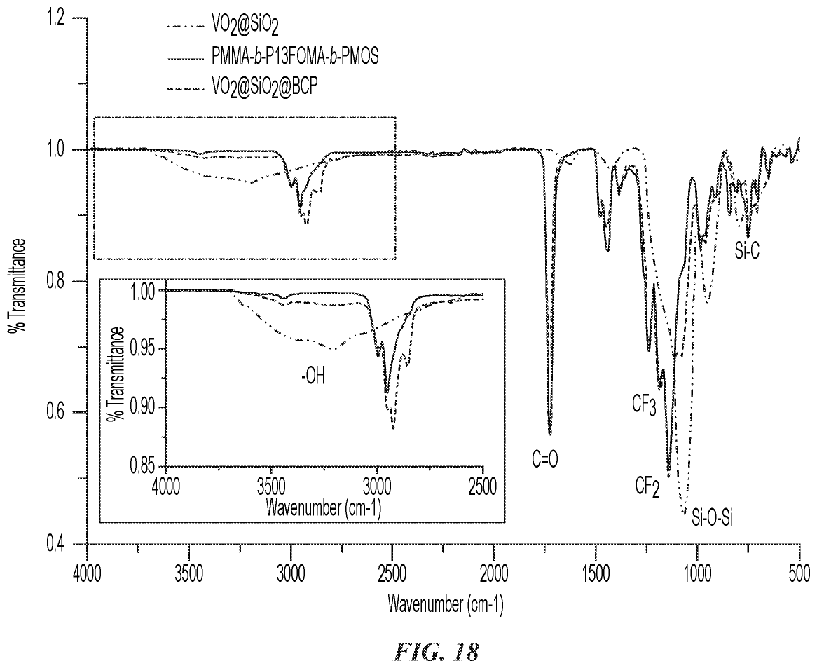

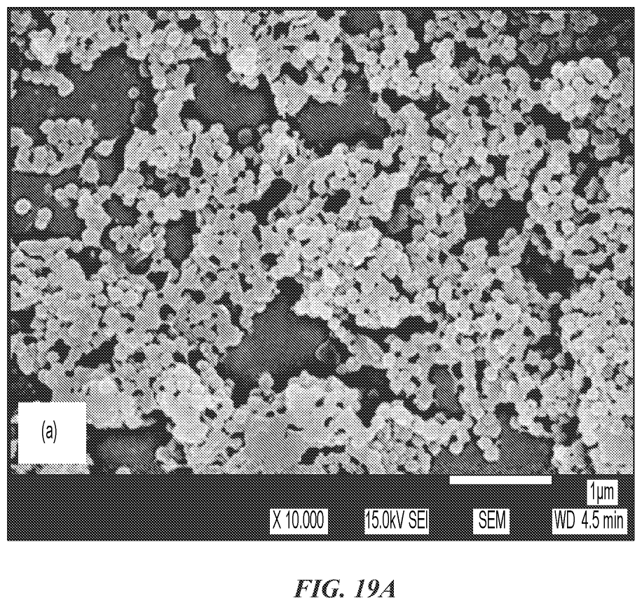

To study the effect of PMMA and P13FOMA copolymer sequences on the efficiency of cloaking the VO₂ NPs, tri-block copolymer PMMA-b-P13FOMA-b-PMOS was prepared using RAFT polymerization, where each component was sequentially introduced into the copolymer, as shown in FIG. 15. The polymer that was formed was also characterized with ¹H and ¹⁹F NMR, SEC, and FTIR analyses. For the BCP, characteristic resonance peaks appeared in both ¹H and ¹⁹F NMR analyses, as is further described below (FIG. 16 and FIGS. 17B-17C). SEC results revealed that the number average molecular weight of the prepared BCP was 33,300 g mol⁻¹ and Ð was 1.211, which indicated a narrow distribution of the MW. Characteristic vibration peaks for respective functional groups in the BCP were also found in the FTIR analysis (FIG. 18).

The as-synthesized GCP or BCP was anchored over the VO₂@SiO₂ NPs using a silatrane moiety, present in both the GCP and the BCP (FIG. 7). This process allowed the core-shell structured VO₂@SiO₂@GCP or VO₂@SiO₂@BCP.

BCP NPs to be obtained and further characterized using SEM and TEM analyses. FTIR analysis also confirmed the presence of GCP (FIG. 13) and BCP (FIG. 18) over the VO₂@SiO₂ NPs. Characteristic peaks for the GCP/BCP were found along with the existence of the vibrational peaks for VO₂@SiO₂, except for a reduction in intensity of the broad vibrational peak at 3420 cm⁻¹, designating the anchoring of the GCP/BCP with the —OH group of silanes.

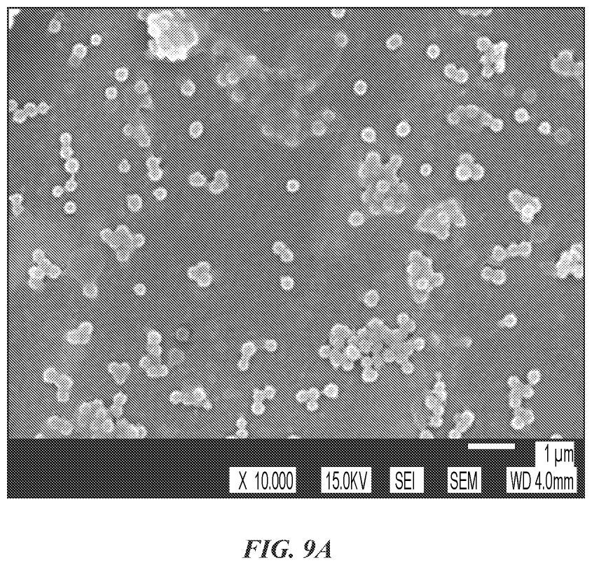

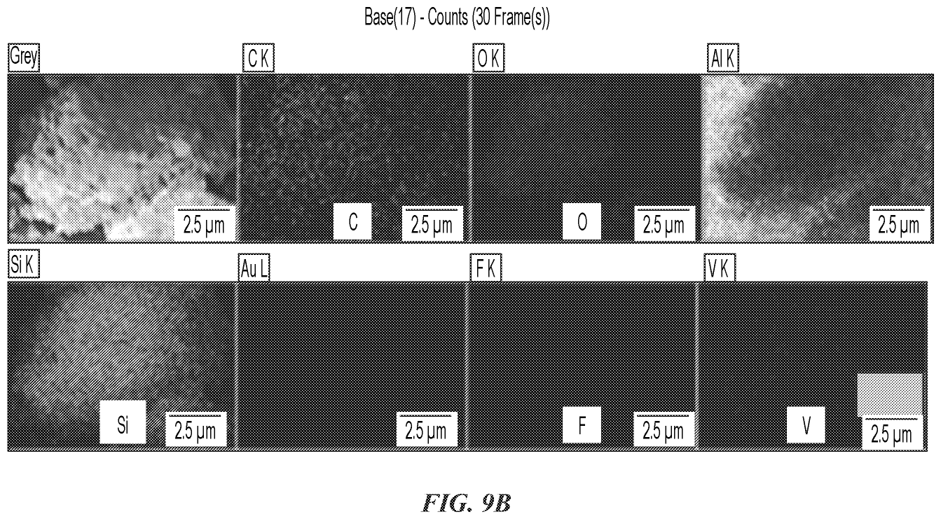

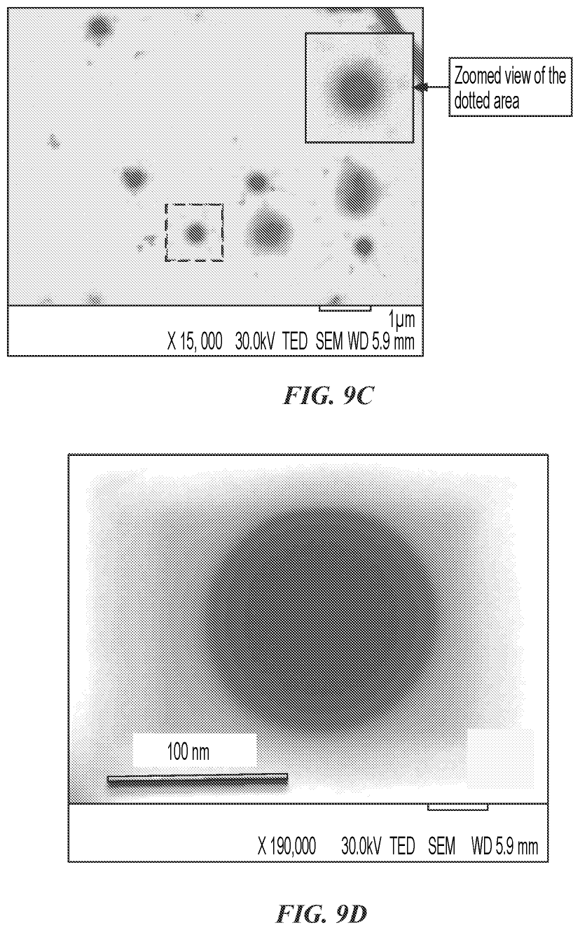

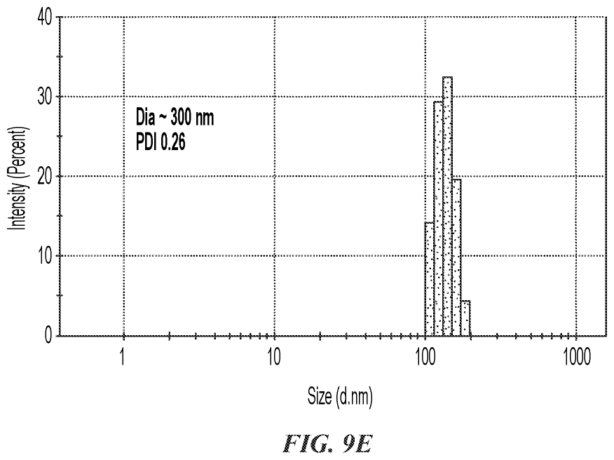

Morphology of the core-shell VO₂@SiO₂@GCP NPs was studied using SEM and TEM analyses. SEM imaging showed spherical NPs with a narrow size distribution. The average particle size obtained was in the range of 160 ±10 nm (FIG. 9A). Elemental mapping was carried out to identify the existence of the elements C, O, Si, F, and V. Presence of Au and Al was also noticed, as prior to the imaging, the sample was coated over the Al sheet and subsequently sputter coated with gold. A bulk area was selected for the mapping, as shown in FIG. 9B, instead of a single sphere to get a clear occurrence of the elements. As SEM imaging is limited to study of the surface morphology, TEM was also taken and clearly showed the existence of the core-shell structure (FIG. 9C), where the GCP formed the outer grey colored layer and the darker core part was formed by the inorganic component (VO₂@SiO₂).

A zoomed TEM image of the core-shell NPs is shown in the inset of FIG. 9C. Indeed, separate layers of SiO₂ and VO₂ were also observed from the TEM study (FIG. 9D). Dynamic light scattering was used to measure the solvated diameter of the core-shell NPs. THF was used as a dispersion solvent. From the machine generated histogram, it was found that the distribution was monomodal and the average diameter of the particles was found to be 300±5 nm with a PDI of 0.26 (FIG. 9E). The obtained PDI designates the spherical shape and uniform distribution of the particles in the dispersion solvent. The higher average particle diameter compared to the SEM and TEM results was due to solvation of the core-shell NPs.

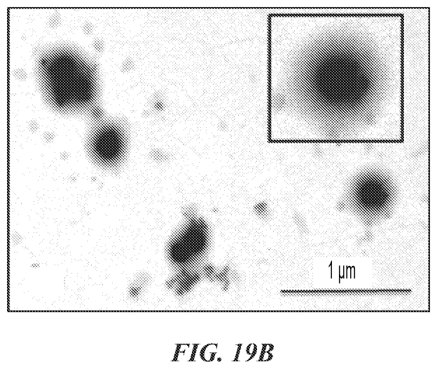

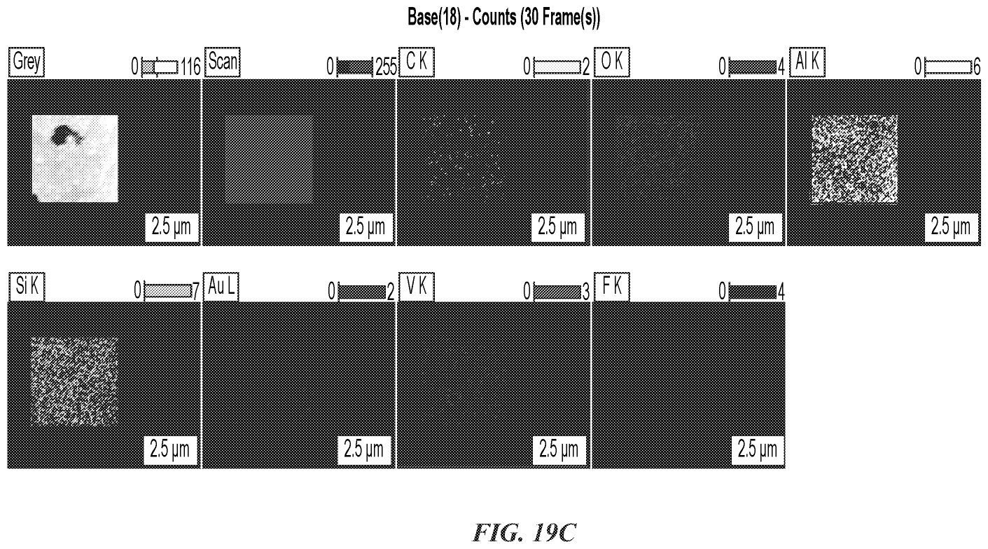

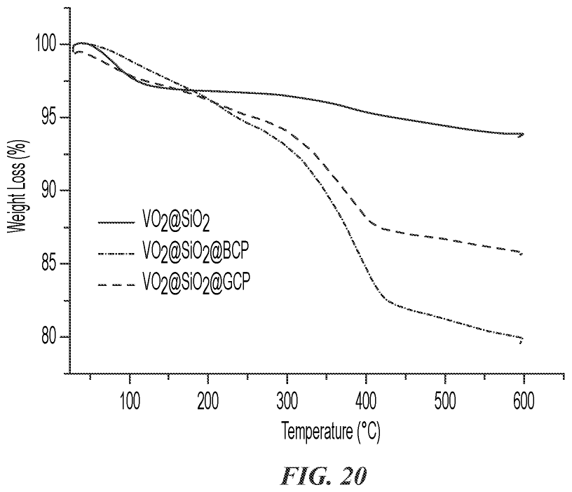

BCP-coated VO₂@SIO₂ NPs were found to have a spherical morphology, similar to the morphologies of the GCP-coated NPs, as confirmed from SEM (FIG. 19A) and TEM (FIG. 19B) analyses. Elemental mapping of VO₂@SiO₂@BCP NPs confirmed the existence of both organic and inorganic components in the nanoparticles. From the TGA analysis (FIG. 20), the weight percentage of the GCP in the VO₂@SiO₂@GCP core-shell structure was determined to be 17 wt %, whereas for BCP it was found to be 20 wt %.

To evaluate the thermochromic behavior of the composite films, the optical properties of the films were investigated using a UV-vis-NIR spectrophotometer in the wavelength range of 300-2200 nm, and at 32° C. and 85° C. respectively. Measurements were performed by varying the loading percentage of VO₂@SiO₂@GCP NPs in continuous PMMA films (20 wt % (GNCF 20), 15 wt % (GNCF 15), 10 wt % (GNCF 10), and 5 wt % (GNCF 5)), as shown in Table 1. Based on the obtained data, the integral visible solar transmittance (Tᵥᵢₛ) was calculated in the range of 400-700 nm and the integral solar transmittance (Tₛₒₗ) was calculated in the range of 300-2200 nm using the following equations;

$${T}_{vis} = {\int }_{400}^{700} {φ}_{vis} ( λ ) T ( λ ) d λ / {\int }_{400}^{700} {φ}_{vis} ( λ ) d λ \qquad [ 1 ]$$

$${T}_{sol} = {\int }_{300}^{2200} {φ}_{sol} ( λ ) T ( λ ) d λ / {\int }_{300}^{2200} {φ}_{sol} ( λ ) d λ \qquad [ 2 ]$$

where T(λ) denotes the transmittance at wavelength λ; φᵥᵢₛ and φₛₒₗ are, respectively, the standard efficiency function for the photopic vision and the solar irradiance spectrum for an air mass of 1.5 (corresponding to the sun standing 37° above the horizon). Solar modulation (ΔTₛₒₗ) of the film was calculated using the following formula:

$$Δ {T}_{sol} = {T}_{sol , L} - {T}_{sol , H} \qquad [ 3 ]$$

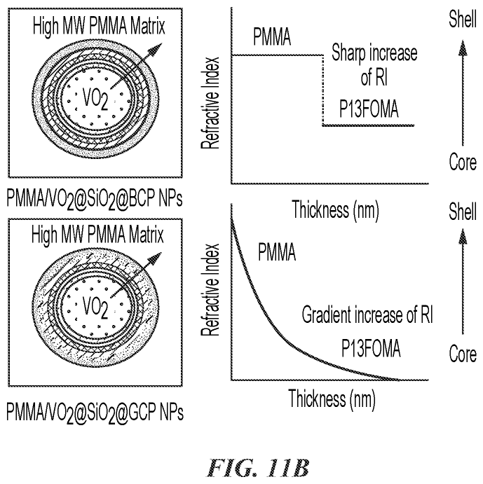

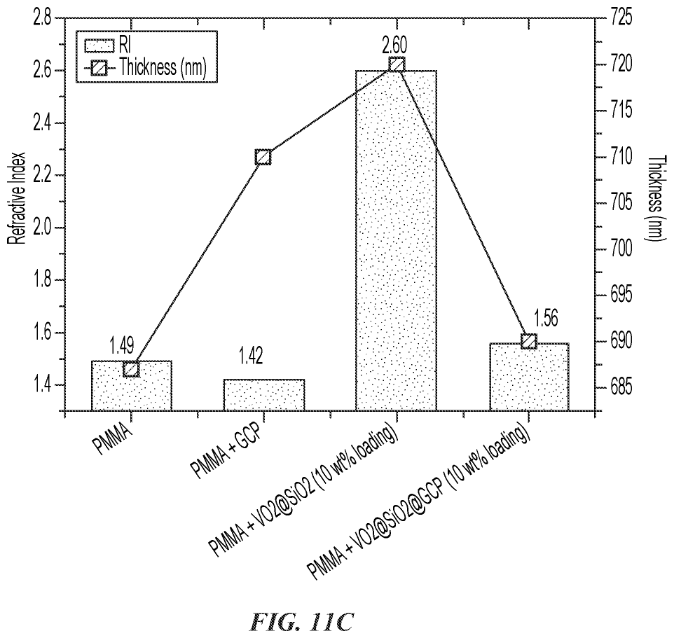

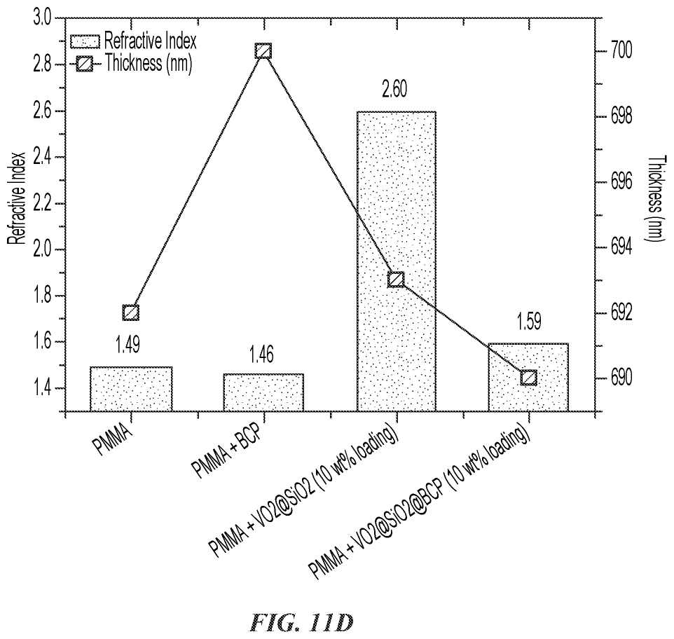

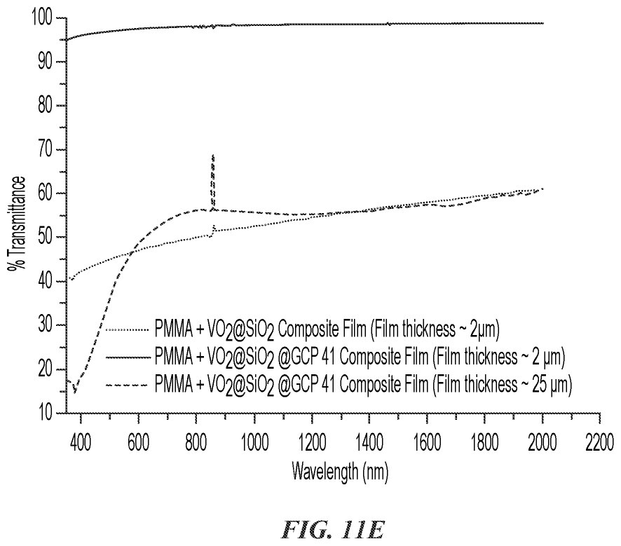

Here, T_{sol,L} and T_{sol,H} are the integral solar transmittance of the VO₂@SiO₂@GCP NPs incorporated composite films at low (32° C.) and high temperature (85° C.) respectively. The obtained values showed that increasing the NPs loading to 20 wt %, improved the solar modulation to 11%, compared to 15 wt % (ΔTₛₒₗ=7%) and 10 wt % (ΔTₛₒₗ=7%) of loading at a coating thickness of −25 μm. The obtained modulation indicates the presence of VO₂ M-phase NPs inside the film. As shown in FIGS. 11E, the modification of VO₂@SiO₂ NPs with the precisely designed GCP improves the clarity of the composite film (% T >90%) containing 10 wt % of composite NPs at a thickness of ˜2 μm, compared to the unmodified one (% T<40%).

Next, the thickness of the coating was increased to ˜25 μm and the percentage loading of NPs was increased to 15 wt % and 20 wt %. A trade-off was observed between ΔTₛₒₗ and % Tᵥᵢₛ. These observations revealed that an increase in the loading of the NPs to 20 wt % and an increase in the thickness of the coating to ˜25 μm improved solar modulation to 11% but produced a % Tᵥᵢₛ of <40%. The best performing composition was found to be the PMMA film with 10 wt % loading of VO₂@SiO₂@GCP NPs (GNCF 10) a and thickness of ˜25 μm (ΔTₛₒₗ=7% and % T_{vis,H}=>55%) (FIG. 11A). The optical parameters are shown in Table 1. Interestingly, while using the BCP-coated VO₂@SiO₂ embedded composite film system, it was observed that at a 10 wt % loading of BNCF 10 NPs, the % T of the composite system decreased significantly to T_{vis,L}/Tᵥᵢₛ.H 48/43 compared to the GCP-based nanocomposite's (GNCF 10) % T value (T_{vis,L}/T_{vis,H} 56/55). This can be explained by considering the alternation in the RI value in GCP and BCP as a function of copolymer sequence.

TABLE 1
Summary of the optical properties of the VO₂@SiO₂@GCP
or BCP NPs embedded PMMA film of ~25 μm thickness
with varying loading percentages of NPs

| Loading % | | ΔT₁₂₀₀ (%) | T_{vis, L}/T_{vis, H} (%) | ΔTₛₒₗ(%) |
|---|---|---|---|---|
| 20 | (GNCF 20) | 10 | 36/28 | 11 |
| 15 | (GNCF 15) | 4 | 41/37 | 7 |
| 10 | (GNCF 10) | 4 | 56/55 | 7 |
| 5 | (GNCF 5) | 2 | 76/75 | 3 |
| 10 | (BNCF 10) | 6 | 48/43 | 7 |
| 5 | (BNCF 5) | 1 | 76/74 | 3 |

Incorporation of particulate material into a transparent polymer matrix that has a different RI value will reduce the optical transparency of resultant film due to light scattering. The relationship between the RI and scattering intensity can be represented as —

$$\frac{I}{{I}_{O}} ∼ {e}^{\frac{- 3 {V}_{p} {xr}^{3}}{4 {λ}^{4}} ( \frac{{n}_{p}}{{n}_{m}} - 1 )} \qquad [ 4 ]$$

where I and Iₒ are the light scattering intensities of the system with and without NPs; r is nanoparticle radius, and nₚ and nₘ are refractive indices for the embedded NPs and matrix respectively. If, nₚ=nₘ, no scattering will occur at the particle-polymer interfaces, leading to the transparent composite material. Along with this, “r” is also an important parameter to control the scattering intensity. Decreasing the NPs radius can improve the scattering and increase the transparency. However, small particle size will raise the surface energy and the composite will again suffer from turbidity due to the agglomeration of too many small NPs. So, stabilization of the particles inside the matrix polymer (e.g., high MW PMMA) is desirable. As a result, the VO₂@SiO₂ NPs were modified with PMMA and fluoropolymer based gradient polymer which assists with dispersion of the particles inside the PMMA matrix. As stated earlier, a tri-block copolymer containing the same composition was prepared to compare the cloaking ability.

With respect to RI matching, the cloaking technology described herein was used to hide the inorganic NPs in the organic matrix by harmonizing the refractive indexes of the two components. VO₂ NPs have an RI of 3, whereas PMMA has a RI of 1.49. There are different options available to prepare transparent nanocomposite films such as fabrication of thin organic-inorganic nanocomposite films, but this approach decreases the VO₂ NPs' concentration inside the film and subsequently the solar modulation (ΔTₛₒₗ). Another approach is to design a nanoporous surface using methods like catalytic etching, oblique angle deposition, lithography, sol-gel process, or chemical vapor depositions. However, all of these processes suffer some limitations, such as lack of high-throughput capabilities, low cost-effectiveness, complicated chemical etching processes, and/or multiple etching processes because of the lack of controllability of n(k). Apart from this, mesoporous surfaces also suffer from a lack of chemical resistivity at high temperatures and in humid conditions.

In this example, the VO₂ NPs (RI=3.00) were modified with either gradient copolymer or block copolymer comprised of P13FOMA (RI 1.33-1.44) and PMMA (RI 1.49). The respective VO₂@SiO₂@GCP or BCP NPs were further dispersed in high MW PMMA (RI 1.49). A schematic of the core-shell structure formed after modification of VO₂@SiO₂ NPs with either GCP or BCP is shown in FIG. 11B.

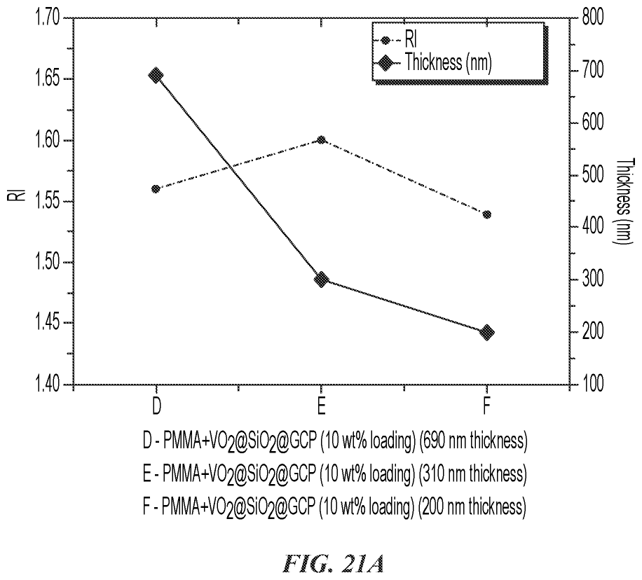

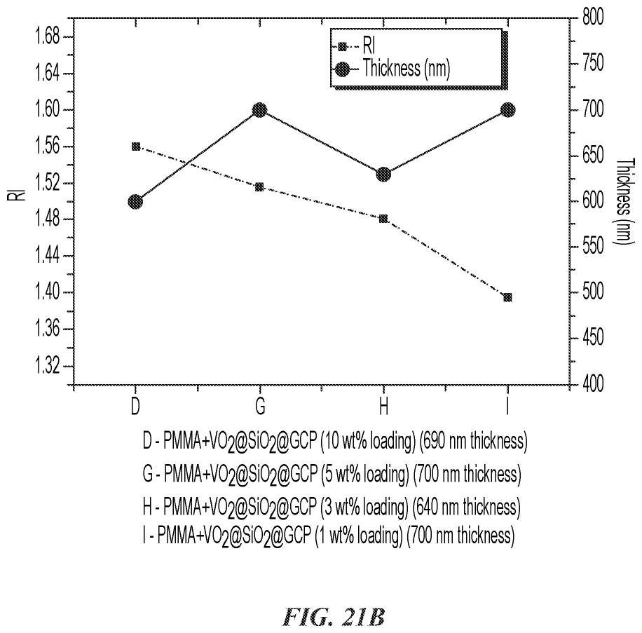

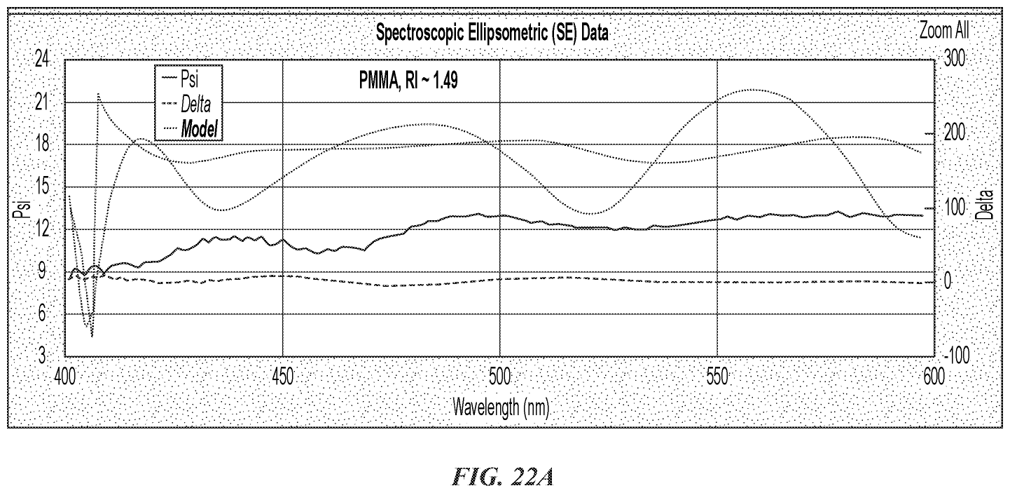

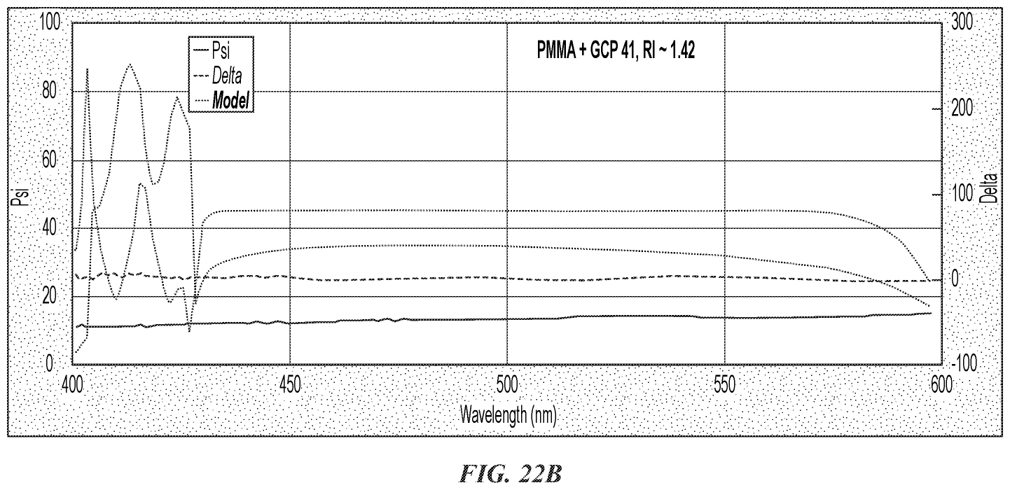

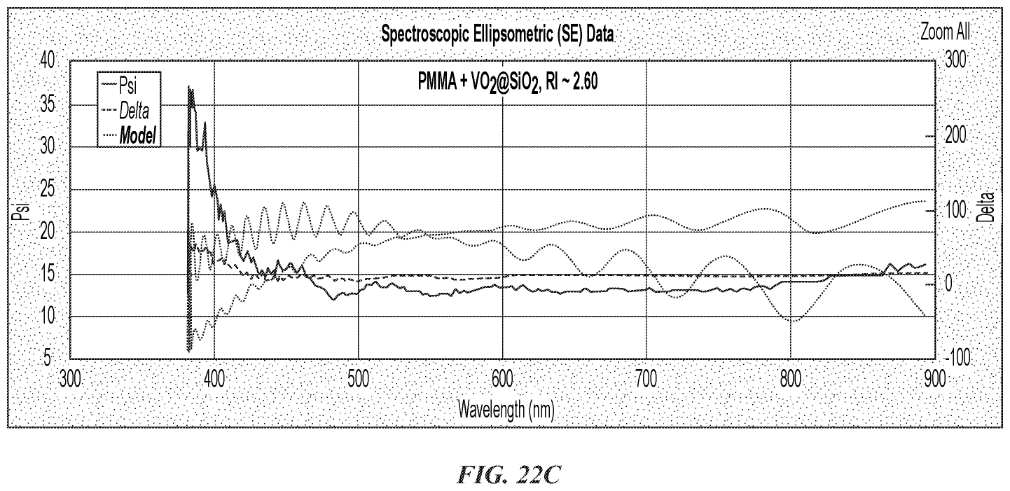

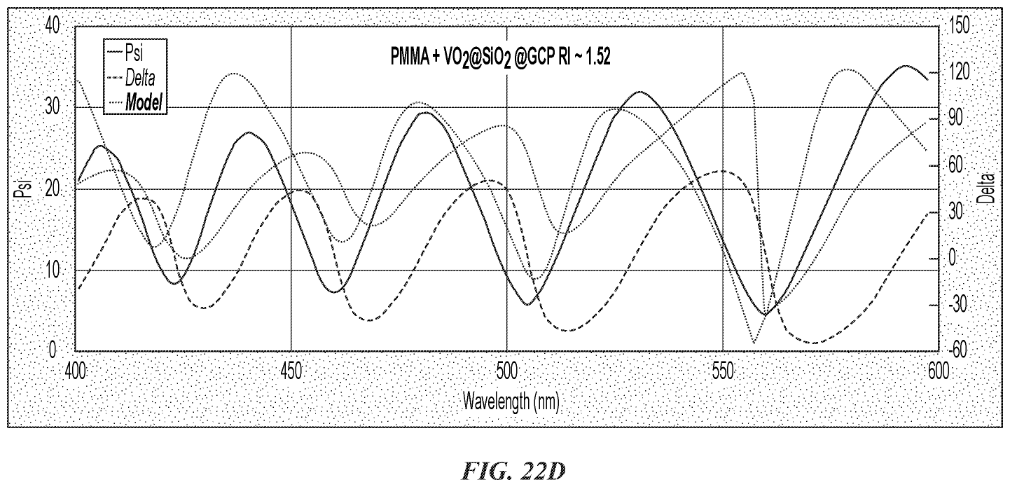

The refractive indexes of the films made from pristine PMMA and from a combination of PMMA with GCP and nanocomposites were obtained from the ellipsometry study. Results are summarized in FIG. 11C. During the measurement, the percentage loading of the VO₂@SiO₂@GCP NPs was varied among 10, 5, 3, and 1 wt % (D, G, H, and I) (FIG. 21A) and thickness of the coating was varied between −200 nm and −700 nm (D, E, and F) (FIG. 21B). It was observed that the PMMA film with GCP-covered inorganic NPs showed an RI of 1.52, which is significantly lower when compared to VO₂@SiO₂ incorporated PMMA film (RI 2.60). The loading percentage of the NPs and the thickness were maintained at 10 wt % and 700 nm, respectively. These index values were determined using the Cauchy model which can be written as representing RI as “n”:

$$n ( λ ) = A + \frac{B}{{λ}^{2}} + \frac{C}{{λ}^{4}} \qquad [ 5 ]$$

where n(λ) is the refractive index at a particular wavelength (here, 633 nm) and A, B, and C are the coefficients. For a particular material, at a known wavelength, this can be determined by fitting the equation to measured refractive indices. The best fit curves for determining the RI of targeted components are shown in FIGS. 22A-22D.

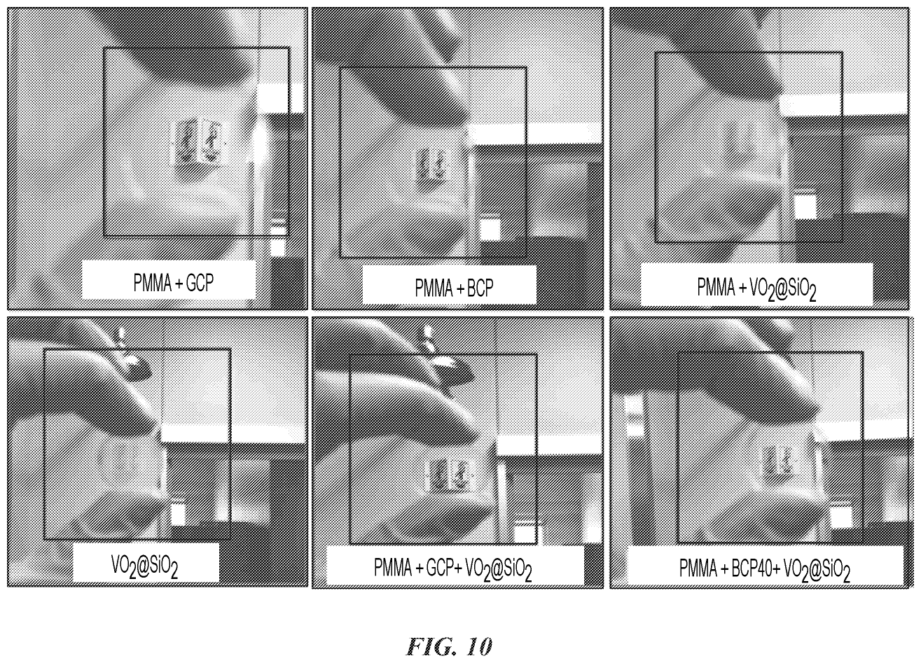

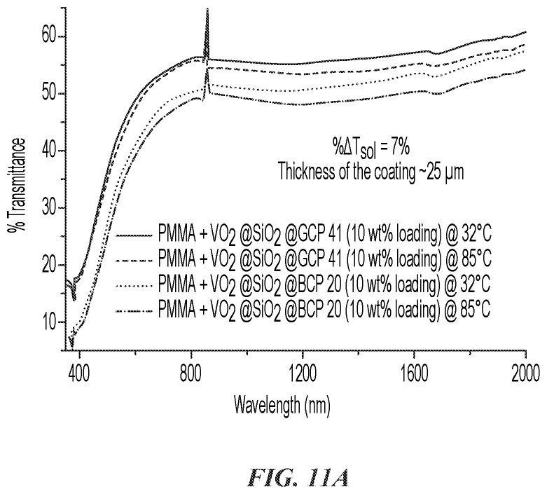

It has been shown that if the refractive index of the matrix, shell, and core are in a sequence of n_{core}>nₘₐₜᵣᵢₓ>nₛₕₑₗₗ, the formed composite film shows transparency. In this example, a similar sequence was precisely maintained (i.e. n_{VO2}>n_{high MW PMMA}>n_{GCP}) to achieve the desired transparency. Images of the coated films with different compositions over the quartz cover slip are shown in FIG. 10. At a coating thickness of −2 μm, VO₂@SiO₂@GCP NPs embedded in PMMA film showed excellent transparency (% transparency >90%, NPs loading 10 wt %) compared to VO₂@SiO₂ NPs infiltrated PMMA film (% transparency <40%). The respective solar modulation (ΔTₛₒₗ) was relatively poor, however. As a result, the thickness of the coating was increased to ˜25 μm to obtain moderate ΔTₛₒₗ. For the composite films, it was found that RI was independent of the film thickness of <1 μm (FIG. 21A), as RI is an intrinsic phenomenon of a material. An increase in the VO₂@SiO₂@GCP NPs loading enhanced the RI value (FIG. 21B). This might be due to a small amount of aggregation of the particles which increases the scattering despite the presence of the GCP coating.

BCP containing compositions were also tested in a similar manner. Variation in the RI value of the nanocomposite film compared to the pristine PMMA is shown in FIG. 11D. Upon modification of the VO₂@SiO₂ NPs with BCP, a drastic drop in the RI value (1.59) was observed, which relates the behavior shown by the GCP modified NPs. Interestingly, % T_{vis,L}/% T_{vis,H} (48/43) of BCP containing nanocomposite film (BNCF 10) was significantly lower compared to % T_{vis,L}/% T_{vis,H} (56/55) of GCP-containing nanocomposite film (GNCF 10), as also reflected in FIGS. 10 and 11A. Both nanocomposite films have comparable RI values, as shown in FIG. 11C and FIG. 11D. It is believed that this may be due to the gradient orientation of PMMA and P13FOMA in the GCP, relative to the block pattern of the same in BCP, as shown FIG. 11B. In BCP, a sharp interface in RI distribution was formed in between the PMMA (RI 1.49) and P13FOMA (RI 1.33) blocks, which may have accelerated the Fresnel reflection, and resulted in a reduction in % T, compared to the gradual variation of the n(λ) in the gradient copolymer. FIG. 11B schematically shows how RI is varied from the high RI core to the low RI Shell. Based on this, it can be concluded that GCP-modified nanoparticles are the best option for this nanocomposite system, compared to the BCP-modified nanoparticles.

The refractive index of the core-shell structured VO₂@SiO₂@GCP NPs was also determined using effective medium theory (EMT) which can be represented as:

$${{n}_{VO 2 @ SiO 2 @ GCP}}^{2} = {{n}_{VO 2 @ SiO 2}}^{2} {V}_{VO 2 @ SiO 2} + {{n}_{GCP}}^{2} {V}_{GCP} + {{n}_{air}}^{2} {V}_{air} \qquad [ 6 ]$$

where, n_{VO2@SiO2@GCP}, n_{VO2@SiO2}, n_{GCP}, and nₐᵢᵣ are the RI of core-shell structured NPs, VO₂@SiO₂, GCP and air, respectively. V_{VO2@SiO2}, V_{GCP}, and Vₐᵢᵣ are the volume fractions of the respective components. Here, the contribution of the air was considered, as the core-shell structure was not compacted, and the presence of air was possible in between the interfaces of the core-shell structure. Volume fraction of the components can be determined as follows:

$$\% {V}_{VO 2 @ SiO 2} = {( \frac{{D}_{VO 2 @ SiO 2}}{{D}_{VO 2 @ SiO 2 @ GCP}} )}^{3} = 42. \% \qquad [ 7 ]$$

$$\% {V}_{GCP} = \frac{17 wt \% \times {V}_{VO 2 @ SiO 2} \times {ρ}_{VO 2 @ SiO 2}}{{ρ}_{GCP}} = 14.94 \% \qquad [ 8 ]$$

$$\% {V}_{air} = 1 - {V}_{Vo 2 @ SiO 2} - {V}_{air} = 43 \qquad [ 9 ]$$

where D_{VO2@SiO2} (˜120 nm) and D_{VO2@SiO2@GCP} (˜160 nm) are the diameters of VO₂@SiO₂, and VO₂@SiO₂@GCP NPs. ρ_{VO2@SiO2}, and ρ_{GCP} are densities of VO₂@SiO₂ NPs, and GCP having a values of 3.35 g cm³ and 1.60 g cm³ respectively; n_{VO2@SiO2}=2.20 and n_{GCP}=1.44, as determined using ellipsometry, and nₐᵢᵣ=1.00 in the visible light wavelength range. So, using Equations 6-9, the RI of VO₂@SiO₂@GCP NPs (n_{VO2@SiO2@GCP}) was calculated as 1.42. The obtained value corroborated the RI of the high MW PMMA matrix (1.49) which was determined using ellipsometry.

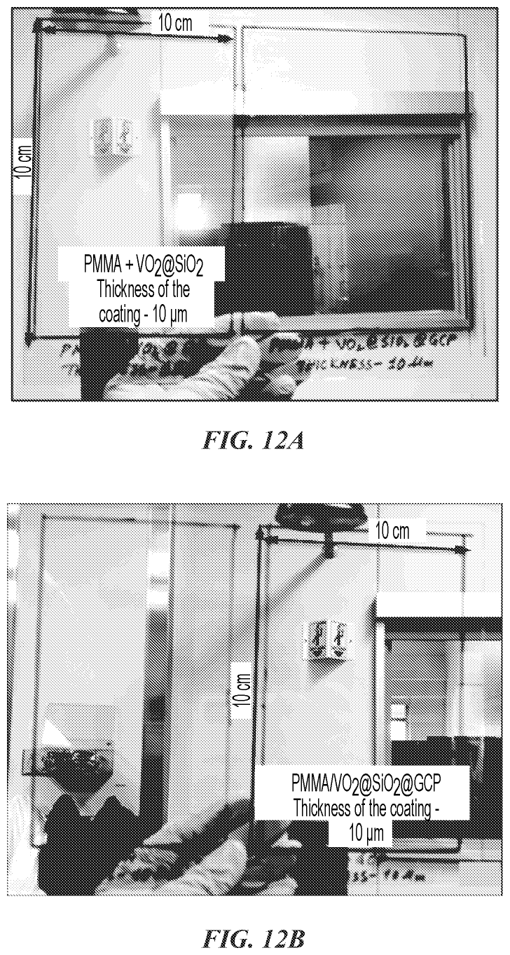

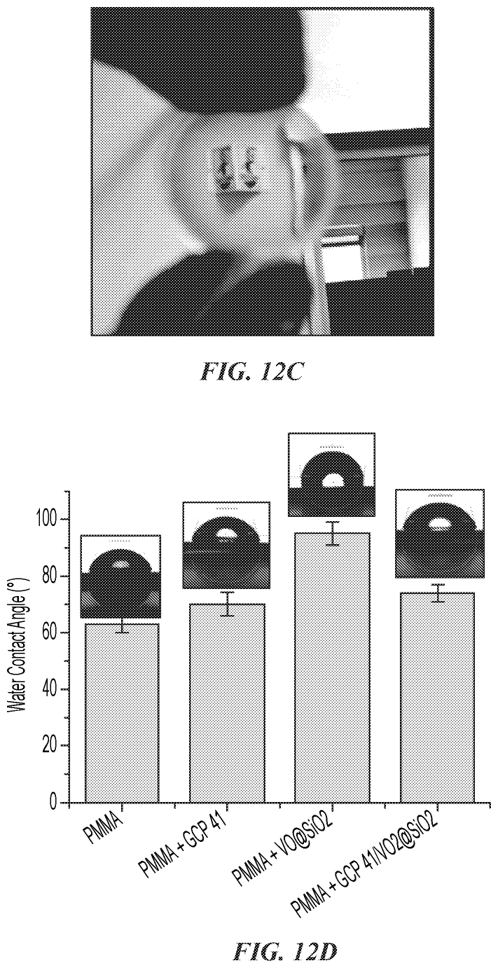

To show the industrial viability of the formulated composition, coating of the GNCF 10 composite solution in THF was carried out over a glass panel (10×10 cm²) using a FOM slot die coater. Coating speed was maintained at 1 m/min and the wet film thickness was maintained at 129 μm to obtain a final dry film thickness of 10 μm. As shown in FIG. 12A, it is clear that pristine VO₂@SiO₂ containing PMMA film showed translucent (left image) behavior, whereas GCP coating over VO₂@SiO₂ NPs improved the transparency (FIG. 12B, right side image). Even at a thickness of ˜25 μm, this composition showed a promising transparency of % T_{vis,L} /% T_{vis,H} (56/55) (FIG. 12C).

Wettability of the pristine PMMA film and the effect of incorporation of the GCP and NPs were observed using water contact angle (WCA) measurement. A small increase in the WCA was observed for GCP incorporated PMMA film (70°) compared to pristine PMMA film (62°). This may be due to the presence of fluorinated polymer in the GCP composition. However, incorporation of the silica-coated VO₂NPs (VO₂@SiO₂) significantly increased the WCA to 95°, as a result of the introduction of a hydrophobic silica layer over the hydrophilic VO₂ surface. Upon incorporation of the gradient copolymer tethered VO₂@SiO₂NPs into the PMMA film, a reduction in the WCA value to 73° was evidenced, indicating the existence of partially hydrophilic PMMA layer over the NPs surface.

### Conclusion

Efficient synthesis of VO₂ NPs, a promising candidate for the thermochromic window glazing application, has been achieved via a specially-designed continuous flow hydrothermal (CFHT) reactor. Results show that the VO₂ NPs improve the low-productivity of the conventional hydrothermal process. Additionally, it is shown herein that subsequent surface modifications with low RI tailor-made fluorinated gradient copolymers resulted in a transparent coating. Accordingly, low RI fluorinated gradient and block copolymers (GCP and BCP) were prepared via ruthenium-catalyzed living radical polymerization and RAFT polymerization respectively to improve the clocking ability of the VO₂@SiO₂ NPs. Interestingly, it was observed that the gradient sequence of PMMA and P13FOMA improved the transparency of the nanocomposite coating compared to the block pattern of the same polymers. From the obtained optical results, it is believed that the presence of the prominent interface between two polymer components of different RI values in the BCP (PMMA 1.49, P13FOMA 1.33-1.44) enhanced the Fresnel reflection, which was not observed in the gradient orientation of the PMMA and P13FOMA in the GCP. It is believed that this imparted transparency to the GCP containing nanocomposite film. A 10 wt % loading of GCP-coated composite nanoparticles in a continuous PMMA (molecular weight 1,20,000 g mol⁻¹) film showed a n(λ) of 1.56 with a percentage visible transmittance (% Tᵥᵢₛ) of ˜56% (thickness ˜25 μm) and solar modulation (ΔTₛₒₗ) of ˜7%.

### Experimental Details

### Materials

Vanadium pentoxide (V₂O₅), oxalic acid dihydrate (C₂H₂O₄·2H₂O), methyl methacrylate (MMA) (monomer), poly(vinylpyrrolidone) (PVP) (MW 10,000 g/mol), tetraethyl orthosilicate (TEOS) (reagent grade, 98%), ethyl-α-chloro phenyl acetate (ECPA), carbonylchlorohydridotris (triphenylphosphine)ruthenium (II) (crystalline)[[(C₆H₅)₃P]₃Ru(CO)(Cl)H], titanium (IV) isopropoxide (Ti(Oᵢ—Pr)₄), 2,2′-Azobis(2-methylpropionitrile) (AIBN) (thermal initiator), 4-Cyano-4-(phenylcarbonothioylthio)pentanoic acid (CTBTPA) (RAFT reagent), molecular sieves (4 Å) (MS 4A), ethanol (EtOH), ammonium hydroxide solution (NH₄OH) (ACS reagent, 28.0-30.0% NH₃ basis) were procured from Sigma-Aldrich, USA. 1H,1H,2H,2H-perfluorooctyl methacrylate (13FOMA) (monomer), methacryloxypropylsilatrane (MOS) (monomer), and 1H,1H,2H,2H-perfluorooctanol (13FOOH) were purchased from TCI chemicals. The MMA and 13FOMA were passed through the inhibitor removing resin before use. Deionized (DI) water was used for the NPs synthesis and dry tetrahydrofuran (THF) was used for the polymer synthesis respectively. Petroleum ether (Sigma-Aldrich) was used as a polymer precipitating solvent.

### Methods

### Preparation of the Precursor

The precursor solution containing 0.0089M [V⁴⁺](4× dilution feed) was prepared using 1 mol of vanadium pentoxide (V₂O₅, 1.29 g) to 4 mol of oxalic acid dihydrate (C₂H₂O₄. 2H₂O, 3.58 g). The solid powders were dispersed in 400 mL of deionized water (DI). The resulting opaque and brownish yellow colored solution was bath ultrasonicated at 60° C. for 3 h until the color of the solution became clear blue. The equations for the reaction are shown in Equations 10, 11 and 12. The as obtained blue colored solution was 4× diluted with DI water and subsequently used for the further step.

V₂O₅ (s)+4(C₂H₂O₄·2H₂O)→[(VO)₂(C₂O₄)₃]²⁺+2H₃O₊+2CO₂+9H₂O [10]

[(VO)₂(C₂O₄)₃]²⁻+2H₃O⁺→2VOC₂O₄+CO+CO₂+3H₂O [11]

2VOC₂O₄→2VO₂+2CO+2CO₂ [12]

Synthesis of VO₂ NPs using Continuous Flow Hydrothermal (CFHT) Reactor

A custom-built continuous flow hydrothermal (CFHT) reactor was used to prepare the VO₂ NPs with controlled shape and size. The CFHT system was installed within a chemical fume hood and ornamented with different safety features including seven thermocouples for temperature observation, a check valve to avoid back-flow, an American Society of Mechanical Engineers (ASME)-stamped and certified rupture disc that would immediately burst in a situation with overpressure, proportional relief valves, and a back-pressure regulator. A computer monitoring system with a specially designed program was installed with the circulation heater and all the thermocouples for a real-time monitoring of the system condition. A schematic of the whole CFHT system is shown in FIGS. 5A-5C.

During the NP synthesis procedure, the chiller (as depicted in FIGS. 5A-5C) was turned on to maintain the reaction zone temperature where supercritical water was used to prepare the VO₂ NPs. In the next step, all pumps (e.g., 1, 2, 3, and 4), which were initially connected to DI water, were initiated to achieve the desired pressure of 22-24 MPa (at and above the supercritical water pressure). After that, the circulation heater was turned on and once the required temperature (>374° C., supercritical temperature of water) was reached, a precursor solution was injected to the CFHT system using Pump 1 to start the NP synthesis. Once the precursor solution met the supercritical water (room temperature water was purged into the system using Pump 4) inside the reaction zone of the CFHT micro-reactor, the desired VO₂ NPs were produced. The resulting colloidal solution was immediately quenched using room temperature DI water, and pumped using Pump 3 before passing through the heat exchanger, 45 μm mesh filter, and the back-pressure regulator. Finally, the blackish green colored VO₂ NPs were collected in a collection container and the size of the NPs was measured using DLS analysis after being cooled down to the room temperature. It should be noted that at different points of the reactor system, several thermocouples and pressure gauges were installed to monitor the temperature and flow rate. These colloidal NPs were then isolated via centrifugation at 9000 rpm in the presence of ethanol and subsequently dried under vacuum at 50° C. before conducting the next step of modifications.

Synthesis of VO₂@SiO₂NPs Using Modified Stöber Process

During the modification procedure, the powdered VO₂ NPs (500 mg, 6 mM) were initially treated with an aqueous solution of PVP (0.026 g/mL, 30 mL total volume) under vigorous stirring condition for 24 h at room temperature (r.t.) to ensure complete adsorption of PVP over the NPs. After that, the resulting solution was transferred to 30 mL of ethanol under continuous stirring conditions, followed by the drop-wise addition of 4 mL ethanol solution of TEOS (10 mL) and 5 mL of aq. ethanol solution of NH₄OH (5 mL) to motivate the hydrolysis of TEOS. Finally, the reaction was continued for 12 h at 60° C. After completion of the reaction, the resultant colloidal silica coated VO₂ NPs (VO₂@SiO₂) were purified via 5 times centrifugation at 8000 rpm and successively washed with DI water and ethanol. The centrifuged product was vacuum dried for 12 h at 50° C.

### Preparation of Sequential PMMA/P13FOMA Gradient Copolymer (GCP) Followed by Silatrane (PMOS) Block Copolymer Via Tandem Catalysis Living Radical Polymerization (LRP)

Synthesis of the gradient copolymers comprising PMMA and P13FOMA (PMMA-grad-P13FOMA) was carried out using the syringe technique inside a two neck air-tight RB flask (200 mL) under inert atmosphere (N₂). In a typical synthesis technique (Entry 1 of Table 2), molecular sieves (MS 4A) (2 g) were initially placed and dried inside the RB under reduced pressure using a heat gun, and 2 mL dry THF solution of the ruthenium-based catalyst [[(C₆H₅)₃P]₃Ru(CO)(Cl)H](30 mg, 0.036 mM) was charged. After that, 4 mL THF solutions of Ti(Oᵢ—Pr)₄ (408 mg, 1.44 mM) and ECPA (72 mg, 0.36 mM) were added sequentially, followed by the addition of the monomer MMA (3.6×10³ mg, 36 mM) and alcohol 13FOOH (2.2×10³ mg, 36 mM), which during reaction will undergo transesterification reaction with MMA under N₂ atm and at 25° C. temperature. The total volume of the solution was 30 mL. All components were mixed thoroughly and placed in an oil bath, which was preheated at 80° C. During the concurrent tandem catalysis (CTC) polymerization of MMA and 13FOOH, the molar ratios of these two components were varied to 1:1, 3:1 and 4:1 respectively before addition of the next monomer MOS. The reaction was allowed to continue for 24 h to achieve maximum conversion. After 24 h, 5 mL THF solution of MOS (108 mg, 0.36 mmol) monomer was added slowly to the reaction mixture using a syringe under continuous stirring conditions and N₂ atm. to conduct sequential tandem catalysis reaction to obtain the copolymer of PMMA, P13FOMA, and PMOS (PMMA-grad-P13FOMA-block-PMOS). The reaction was allowed to continue for 8 h. After the predetermined time interval, the mixture was rapidly quenched by dipping the reaction vessel into the ice water. The resultant mixture was precipitated using petroleum ether and purified via re-precipitation method 3 times before ¹H NMR was performed to find the percent cumulative composition of each polymer. The purified polymer was vacuum dried at 50° C. and a final white colored product was obtained (Yield 77%, determined by gravimetric method) and named as GCP 11. Respective compositions are shown in Table 2. The obtained product was characterized using ¹H NMR, ¹⁹F NMR, FTIR, and SEC analyses. [¹H NMR, 400 MHz, 25° C., CDCl₃ (δ=7.26), δ (ppm)=7.38-7.48 (aromatic); for P13FOMA- δ(ppm) −4.24 (—COO—CH₂—), 2.3-2.1 (—CF₂—CH₂—CH₂—), 2.1-1.4 (—C(CH₃)—CH₂—), 1.30-0.6 (—C(CH₃)—CH₂—); for PMMA—δ (ppm)=3.59 (—COO—CH₃), 2.1-1.4 (—C(CH₃)-CH₂-), 1.30-0.6 (—C(CH₃)—CH₂—); for PMOS—δ (ppm)=3.97 (—COO—CH₂—CH₂—), 3.73 (—Si—O—CH₂—). ¹⁹F NMR., 400 MHz, 25° C., CDCl₃, δ (ppm)=−80.77 (—CF₃), −113.42 (—CH₂—CF₂—CF₂—), −121.79 (—CF₂—CF₂—CF₂—), −122.79 (CF₃—CF₂—CF₂—), −123.53 (—CH₂—CF₂—CF₂—), −126.18 (CF₃—CF₂—). A similar method was performed for the other compositions of copolymers, and they were named GCP 31 and GCP 41, respectively.

TABLE 2
Synthesis of PMMA-grad-P13FOMA-block-PMOS via concurrent followed by sequential tandem
catalysis living radical polymerization of MMA with fluoroalcohol (13FOOH) and MOS^{a,b}

| | [13FOOH] | [MMA] | [MOS] | | [Ru-cat] | [ECPA] | [Ti(Oᵢ—Pr)₄] | Mn^{c} | |
|---|---|---|---|---|---|---|---|---|---|
| Entry | (mmol) | (mmol) | (mmol) | [MMA]:[13FOOH]:[MOS] | (mmol) | (mmol) | (mmol) | (gmol⁻¹) | Ð^{c} |
| 1 | 36 | 36 | 0.36 | 1:1:0.01 | 0.036 | 0.36 | 1.44 | 25,000 | 1.838 |
| 2 | 12 | 36 | 0.36 | 3:1:0.01 | 0.036 | 0.36 | 1.44 | 16,700 | 2.151 |
| 3 | 9 | 36 | 0.36 | 4:1:0.01 | 0.036 | 0.36 | 1.44 | 15,300 | 2.153^{d} |

^{a}[MMA]:[ECPA]:[[[(C₆H₅)₃P]₃Ru(CO)(Cl)H]:[Ti(Oᵢ—Pr)₄] = 1000:10:1:40 mmol;
^{b}all the reactions carried out in presence of MS 4A (2 g) at 80° C. and N₂ atm.;
^{c}Mₙ and Ð were determined using SEC;
^{d}% cumulative composition of individual segment of PMMA-grad-P13FOMA-block-PMOS copolymer for Entry 3 (GCP 41) is PMMA = 74%, P13FOMA = 22%, and PMOS = 4% (determined using ¹H NMR analysis).

Synthesis of Tri-block Copolymer Poly(methyl methacrylate)-block-poly(1H,1H,2H,2H-perfluorooctyl methacrylate)-block-poly(methacryloxypropylsilatrane) [PMMA-b-P13FOMA-b-PMOS] via RAFT Polymerization

### Synthesis of PMMA Homopolymer

MMA (10 g, 9.98 mmol) and CTBTPA RAFT reagent (0.068 g, 0.248 mmol) were taken in a 100 mL round-bottomed (RB) flask and 12 mL of dry THF was purged into it under nitrogen atmosphere (N₂ atm). The solution was stirred for 30 min under N₂ atm and 2 mL THF solution of the thermal initiator AIBN (0.0123 g, 7.48×10⁻² mmol) was added into the reaction mixture after that. The reaction was allowed to continue for 12 h at 70° C. before quenching by dipping into ice-cold water. Polymer was precipitated using petroleum ether. ¹H NMR and SEC studies were performed and the percent conversion was found to be 80%. Two sets of PMMA were synthesized having degree of polymerization (DP) of 400 and 200 respectively. [¹H NMR, 400 MHz, 25° C., CDCl₃ (6=7.26), δ (ppm)=3.59 (—COO—CH₃), 2.1-1.4 (—C(CH₃)—CH₂—), 1.30-0.6 (—C(CH₃)—CH₂—)]

### Preparation of PMMA-b-P13FOMA Di-Block Copolymer Using PMMA as a Macro-RAFT Reagent

To prepare the di-block copolymer, synthesized PMMA having a RAFT end group was used as a macro-RAFT reagent. For the polymerization reaction, PMMA₂₀ (7 g, 4.39×10⁻⁴ mmol) was dissolved in 10 mL of dry THF, placed in a RB, and the monomer 13FOMA (8.75 g, 0.02 mmol) was added to the solution. The reaction mixture was stirred for 10 min under N₂ atm and after that 2 mL dry THF solution of AIBN (0.0525 g, 1.32×10⁻⁶ mmol) was charged into the reaction mixture under N₂ atm and stirred for another 20 min before being placed into an oil bath at 70° C. The reaction was allowed to continue for 24 h and the product was isolated by precipitation in petroleum ether, followed by drying under vacuum at 50° C. The as-prepared polymer was characterized using ¹H and ¹⁹F NMR, and SEC analyses. [¹H NMR, 400 MHz, 25° C., CDCl₃ (δ=7.26), δ (ppm)=4.24 (—COO—CH₂—), 2.3-2.1 (—CF₂—CH₂—CH₂—), 2.1-1.4 (—C(CH₃)—CH₂—), 1.30-0.6 (—C(CH₃)—CH₂—); ¹⁹F NMR, 400 MHz, 25° C., CDCl₃, δ (ppm)=−82.13 (—CF₃), −114.33 (—CH₂—CF₂—CF₂—), −122.70 (—CF₂—CF₂—CF₂—), −123.65 (CF₃—CF₂—CF₂—), −124.51 (—CH₂—CF₂—CF₂—), −127.27 (CF₃—CF₂—)] Polymerization of methacryloxypropylsilatrane (MOS) using PMMA-b-P13FOMA as a macro-RAFT Reagent (PMMA-b-P13FOMA-b-PMOS) Tri-block copolymer (PMMA-b-P13FOMA-b-PMOS) was synthesized using PMMA-b-P13FOMA as a macro-RAFT agent. PMMA₂₀-b-P13FOMA₁₀ (5 g, 1.6×10⁻⁴ mmol) was dissolved in 10 mL of dry THF and silatrane monomer (0.854 g, 2.84×10⁻³ mmol) was added afterward. The resulting solution was stirred for 40 min to completely solubilize the monomer into the solvent, as this is a sparingly soluble solid in the used solvent. Then 2 mL THF solution of AIBN was drop wise added into the solution and purged with N₂ for 30 min before transferring the mixture into the oil bath, pre-set at 70° C. The reaction was allowed to carry out for 12 h and the formed product was isolated by precipitating in pet. ether followed by vacuum drying at 50° C. for 1 day. Product was characterized using ¹H NMR and SEC. [¹H NMR, 400 MHz, 25° C., CDCl₃ (δ=7.26), δ (ppm)=3.92 (—COO—CH₂—CH₂—), 3.76 (—Si—O—CH₂—)]

Preparation of GCP-Tethered VO₂@SiO₂ Core-Shell NPs (VO₂@SiO₂@GCP) and Fabrication of the Composite Film

The as-synthesized VO₂@SiO₂ NPs were further modified with the low RI gradient copolymer via sol-gel method. For surface modification of the NPs, initially, in a 100 ml two neck round bottomed flask (closed with septum), 500 mg of VO₂@SiO₂ NPs were dispersed in 20 ml of dry THF via ultrasonication for 10 min. After that, the NPs dispersion was placed in an oil bath having a pre-set temperature of 65° C., and dry THF solution (20 ml) of GCP (700 mg) was drop-wise added to the NPs dispersion under vigorous stirring condition and in an inert atmosphere (N₂ atm). The weight ratio of polymer to NPs was maintained at 1.5:1. The reaction was allowed to continue for 12 h at the mentioned temperature and after that the product (VO₂@SiO₂@GCP) was isolated via centrifugation at 8000 rpm and washed with acetone three times. The final product was dried under vacuum at 50° C. for 12 h (Yield—90%). The surface modification of VO₂@SiO₂ NPs with the GCP was confirmed by FTIR analysis and diameter of the particles was determined using dynamic light scattering (DLS) analysis. A similar approach was also taken to anchor BCP over the surface of VO₂@SiO₂ NPs.

The composite film was fabricated by dispersing VO₂@SiO₂@GCP/BCP NPs in a continuous high MW PMMA (1,20,000 g/mol) matrix. For this, initially, 20 ml of a 5 wt % PMMA solution was prepared by dissolving commercial PMMA in THF. The resultant solution was separated into four sets and NPs were dispersed at a different loading percentage (such as 20, 15, 10, and 5 wt %) in different sets via ultrasonication followed by vigorous stirring to get a homogenous composite solution. The solutions were spin coated over quartz cover slip to get thin coating (up to ˜2 μm) and drop casted for thick coating (above 2 μm).

Per the loading, the nanocomposite films were named GNCF 20, GNCF 15, GNCF 10, and GNCF 5, respectively. Similarly, for the BCP containing nanocomposite, films were designated as BNCF 20, BNCF 15, BNCF 10, and BNCF 5, respectively. For the ellipsometry study, the composite solution was spin coated over a silicon wafer.

### Characterizations

Presence of the different functional groups in the prepared samples was analyzed using a Fourier transform infrared spectroscopy (FTIR) spectrophotometer (Bruker Platinum ATR) at the scanning range and frequency of 500-4000 cm⁻¹ and 32 scans, respectively. ATR mode was used for the measurement. ¹H NMR and ¹⁹F NMR spectra of the polymer samples were measured in Bruker 400 MHz instrument using deuterated chloroform (CDCl₃) as an NMR solvent at ambient temperature and tetramethyl silane (TMS) as an internal standard. Molecular weight and the polydispersity (D) of the synthesized polymers were determined using size exclusion chromatography (SEC) (Wyatt/Schimadzu size exclusion chromatography instrument, Shimadzu HPLC LC20-AD, eluent-THF, 2 Agilent PLgel 5 um MIXED-D+guard SEC columns). The flow rate was maintained at 1.0 mL min⁻¹ and the calibration was executed using narrow dispersed polystyrene standards of MW range between 200-4,00,000 g mol⁻¹. Surface morphologies of the prepared NPs were observed using a JEOL 7500 scanning electron microscopy (SEM) at an accelerating voltage of 5 kV. For the sample preparation, the NPs were first dispersed in acetone by ultrasonication at a concentration 1 mg mL- and then drop casted over a thick aluminum (Al) sheet. The rectangular cut small Al sheets were ultrasonicated in acetone for 30 min before use. Prior to the imaging, polymer coated NPs (VO₂@SiO₂@GCP) were gold sputter coated (SPI-MODULE Sputter Coater) to increase the thermal conductivity and avoid burning of the polymer under high energy accelerating electron beam. All the sample-coated Al sheets were placed over stubs using carbon adhesive tape. Bulk morphology of the synthesized VO₂@SiO₂@GCP NPs was imaged using JEOL 7500 instrument with an accelerating voltage of 30 kV and total energy detector (TED) mode selected. Samples (conc. 1 mg mL⁻¹) were drop-casted over carbon-coated TEM grid having 300 mesh sizes and dried at room temperature for 24 h before imaging. Hydrodynamic diameters of the prepared NPs were measured using dynamic light scattering (DLS) instrument (Malvern Nano ZS) having a He—Ne source (4 mW, λ=632.8 nm) and scattering angle was set at 90°. All measurements were carried out at room temperature and concentrations of the NPs (prepared in THF) dispersions were kept at 1 mg mL⁻¹. Temperature-dependent percentage transmittance (% T) of the composite films both at low (32° C.) and high (85° C.) temperature were measured in the wavelength (k) range of 350-2200 nm using PerkinElmer Lambda 950 UV-vis-NIR Spectrometer. Heating and cooling of the samples were carried out using PIKE heating instruments and PIKE recirculatory, respectively. XRD measurement was carried out in Bruker D8 Advance instrument. A scanning range of 5° to 80° was fixed for the experiment to run. Refractive index (RI) and the thickness of the coating were measured using Ellipsometer (J. A. Woollam Co., Inc., α-SE). Before the testing, the samples were spin-coated over silicon wafer and the coating thicknesses were varied by modulating the speed of the instrument. Along with the thickness, the percentage loading of the NPs was also varied. The Cauchy model was utilized to fit the machine generated signal at a preset wavelength (λ=633 nm) for a particular film composition. The phase transition temperatures of the VO₂ and VO₂@SiO₂ NPs were measured using differential scanning calorimetry (DSC) analysis (NETZSCH STA 449F3 STA449F3A-0296-M). Samples were sequentially heated and cooled two times at a heating range of 40° C.-160° C. and at a rate of 20° C. min- under N₂ atm. The thermogram obtained from the 2^{nd} heating cycle was taken for the analysis. A similar instrument was used to characterize the BCP and GCP. Percentage composition of the polymer to inorganic NPs in VO₂@SiO₂@GCP or BCP NPs was determined using thermogravimetric (TGA) analysis (Metier Toledo, TGA/SDTA851). The sample was heated in an aluminum crucible from 32° C. to 600° C. at a heating rate of 10° C. min⁻¹. From the ash content, the percent composition was calculated. For the film fabrication, a FOM slot die coater was used. To check the change in water contact angle (WCA) of the composite film upon incorporation of the different NPs, KROSS Advance instrument was used.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A nanoparticle, comprising:
a core region comprising a thermochromic material; and
a shell region around the core region,
wherein:
a first location within the shell region has a first constructive refractive index with respect to a wavelength of visible electromagnetic radiation at 25° C.;
a second location within the shell region that is farther from the core region than the first location within the shell region has a second constructive refractive index with respect to the wavelength of visible electromagnetic radiation at 25° C.;
a third location within the shell region that is farther from the core region than the first location and the second location within the shell region has a third constructive refractive index with respect to the wavelength of visible electromagnetic radiation at 25° C.;
a fourth location within the shell region that is farther from the core region than the first location, the second location, and the third location within the shell region has a fourth constructive refractive index with respect to the wavelength of visible electromagnetic radiation at 25° C.;
the second constructive refractive index is less than or equal to 0.9 times the first constructive refractive index;
the third constructive refractive index is less than or equal to 0.9 times the second constructive refractive index; and
the fourth constructive refractive index is less than or equal to 0.9 times the third constructive refractive index.

2. A nanoparticle, comprising:
a core region comprising a thermochromic material; and
a shell region around the core region, the shell region comprising a polymer,
wherein:
the core region has a refractive index with respect to at least one wavelength of visible electromagnetic radiation at 25° C.; and
the shell region has a refractive index with respect to the wavelength of visible electromagnetic radiation at 25° C. that is less than or equal to 0.9 times the refractive index of the core region.

3. The nanoparticle of any one of claims 1-2, wherein the shell region comprises a gradient copolymer.

4. The nanoparticle of claim 3, wherein the gradient copolymer extends in a direction outward from the core region to an exterior of the shell region.

5. The nanoparticle of any one of claims 1-4, wherein the polymer in the shell region is an organic polymer.

6. The nanoparticle of any one of claims 1-5, wherein the polymer in the shell region is tethered to the core region via a linker moiety.

7. The nanoparticle of any one of claims 1-6, wherein the thermochromic material comprises a metal oxide.

8. The nanoparticle of any one of claims 1-7, wherein the thermochromic material comprises VO₂.

9. The nanoparticle of any one of claims 1-8, wherein the thermochromic material is at least partially surrounded by SiO₂.

10. The nanoparticle of any one of claims 1-9, wherein, for at least 50% of all wavelengths of visible electromagnetic radiation, the constructive indices of refraction at the second location within the shell region are less than or equal to 0.9 times the corresponding constructive indices of refraction at the first location within the shell region, the constructive indices of refraction at the third location within the shell region are less than or equal to 0.9 times the corresponding constructive indices of refraction at the second location within the shell region, and the constructive indices of refraction at the fourth location within the shell region are less than or equal to 0.9 times the corresponding constructive indices of refraction at the third location within the shell region.

11. The nanoparticle of any one of claims 1-10, wherein, over at least 50% of the distance through the shell region, in a direction from an exterior of the core region to an exterior of the shell region, and following a line segment that begins at the geometric center of the nanoparticle and extends outward to the exterior of the shell region, the constructive refractive index of the shell region is decreasing.

12. The nanoparticle of any one of claims 1-11, wherein, over at least 50% of the distance through the shell region, in a direction from an exterior of the core region to an exterior of the shell region, and following a line segment that begins at the geometric center of the nanoparticle and extends outward to the exterior of the shell region, the constructive refractive index of the shell region is monotonically decreasing.

13. The nanoparticle of any one of claims 1-12, wherein the shell region has a thickness of at least 50 nanometers.

14. The nanoparticle of any one of claims 1-13, wherein the core region has a maximum cross-sectional dimension of less than or equal to 500 nanometers.

15. A collection of nanoparticles, wherein:
each nanoparticle comprises:
a core region comprising a thermochromic material having a refractive index with respect to a wavelength of visible electromagnetic radiation at 25° C.; and
a shell region; and
the nanoparticles can be arranged in a matrix material having a refractive index with respect to the wavelength of electromagnetic radiation at 25° C. that is less than or equal to 0.9 times the refractive index of the core region material for that wavelength of electromagnetic radiation at 25° C., such that:
when the nanoparticles are evenly distributed within a layer having a thickness of 25 micrometers at 10 wt %, then, at least 50% of the incident visible electromagnetic radiation of the wavelength is transmitted through the layer.

16. The collection of nanoparticles of claim 15, wherein the thermochromic material comprises a metal oxide.

17. The collection of nanoparticles of any one of claims 15-16, wherein the thermochromic material comprises VO₂.

18. The collection of nanoparticles of any one of claims 15-17, wherein the thermochromic material is at least partially surrounded by SiO₂.

19. The collection of nanoparticles of any one of claims 15-18, wherein, for each nanoparticle, over at least 50% of the distance through the shell region, in a direction from the exterior of the core region to the exterior of the shell region, and following a line segment that begins at the geometric center of the nanoparticle and extends outward to the exterior of the shell region, the constructive refractive index of the shell region is decreasing.

20. The collection of nanoparticles of any one of claims 15-19, wherein, for each nanoparticle, over at least 50% of the distance through the shell region, in a direction from the exterior of the core region to the exterior of the shell region, and following a line segment that begins at the geometric center of the nanoparticle and extends outward to the exterior of the shell region, the constructive refractive index of the shell region is monotonically decreasing.

21. The collection of nanoparticles of any one of claims 15-20, wherein the shell region comprises a polymer.

22. The collection of nanoparticles of any one of claims 15-21, wherein the shell region comprises a gradient copolymer.

23. The collection of nanoparticles of any one of claims 21-22, wherein the polymer is an organic polymer.

24. The collection of nanoparticles of any one of claims 22-23, wherein the gradient copolymer is tethered to the core region via a linker moiety.

25. The collection of nanoparticles of any one of claims 15-24, wherein the shell region has a thickness of at least 50 nanometers.

26. The collection of nanoparticles of any one of claims 15-25, wherein the core region has a maximum cross-sectional dimension of less than or equal to 500 nanometers.

27. A composite material, comprising:
a matrix material having a refractive index with respect to a wavelength of visible electromagnetic radiation at 25° C.; and
nanoparticles dispersed within the matrix material, each of the nanoparticles comprising a thermochromic material having a refractive index with respect to the wavelength of visible electromagnetic radiation at 25° C.;
wherein:
the refractive index of the matrix material with respect to the wavelength of visible electromagnetic radiation at 25° C. is less than or equal to 0.9 times the refractive index of the thermochromic material with respect to the wavelength of visible electromagnetic radiation at 25° C.;
the nanoparticles make up at least 10 wt % of the composite material; and
the composite material has a transmittance of the wavelength of visible electromagnetic radiation of at least 50%.

28. The composite material of claim 27, wherein the thermochromic material comprises a metal oxide.

29. The composite material of any one of claims 27-28, wherein the thermochromic material comprises VO₂.

30. The composite material of any one of claims 27-29, wherein the thermochromic material is at least partially surrounded by SiO₂.

31. The composite material of any one of claims 27-30, wherein each of the nanoparticles comprise a core region and a shell region.

32. The composite material of claim 31, wherein, for each nanoparticle, over at least 50% of the distance through the shell region, in a direction from the exterior of the core region to the exterior of the shell region, and following a line segment that begins at the geometric center of the nanoparticle and extends outward to the exterior of the shell region, the constructive refractive index of the shell region is decreasing.

33. The composite material of claim 31, wherein, for each nanoparticle, over at least 50% of the distance through the shell region, in a direction from the exterior of the core region to the exterior of the shell region, and following a line segment that begins at the geometric center of the nanoparticle and extends outward to the exterior of the shell region, the constructive refractive index of the shell region is monotonically decreasing.

34. The composite material of any one of claims 27-33, wherein, for each nanoparticle, the shell region comprises a polymer.

35. The composite material of any one of claims 27-34, wherein, for each nanoparticle, the shell region comprises a gradient copolymer.

36. The composite material of any one of claims 34-35, wherein the polymer is an organic polymer.

37. The composite material of any one of claims 35-36, wherein the gradient copolymer is tethered to the core region via a linker moiety.

38. The composite material of any one of claims 27-37, wherein, for each nanoparticle, the shell region has a thickness of at least 50 nanometers.

39. The composite material of any one of claims 27-38, wherein, for each nanoparticle, the core region has a maximum cross-sectional dimension of less than or equal to 500 nanometers.

40. The composite material of any one of claims 27-39, wherein the composite material is part of a window, a package, a screen, or a display.

41. The composite material of any one of claims 27-40, wherein the matrix material and the nanoparticles form all or a part of a layer over a surface of a window, a package, a screen, or a display.

42. A method of making a nanoparticle, comprising:
establishing a shell region around a core region to form a nanoparticle of any one of claims 1-14.

43. The method of claim 42, wherein establishing the shell region around the core region comprises coupling a polymer to the core region.

44. The method of any one of claims 42-43, further comprising forming the core region and subsequently establishing the shell region around the core region.

45. The method of any one of claims 42-44, comprising forming the collection of nanoparticles of any one of claims 15-26.

46. A method of making a composite material, comprising:
dispersing nanoparticles within a liquid matrix material; and
solidifying the liquid matrix material such that the nanoparticles are dispersed within the solidified matrix material,
wherein the composite material is the composite material of any one of claims 27-41.
